(19) United States
(12) Patent Application Publication
(10) Pub. No.: US 2011/0237050 A1
(43) Pub. Date: Sep. 29, 2011

(54) METHOD FOR PROCESSING WAFER

(75) Inventors: Toshimasa SUGIMURA, Osaka (JP); Akinori NISHIO, Osaka (JP); Kazuyuki KIUCHI, Osaka (JP)

(73) Assignee: NITTO DENKO CORPORATION, Osaka (JP)

(21) Appl. No.: 13/052,317

(22) Filed: Mar. 21, 2011

(30) Foreign Application Priority Data
Mar. 24, 2010 (JP) 2010-068999

(51) Int. Cl. H01L 21/78

(52) U.S. Cl. 438/465; 257/E21.599

(57) ABSTRACT

The present invention provides a method which includes sticking a surface protection sheet for dicing onto a surface of a wafer and cutting the sheet together with the wafer to protect the surface of the wafer from being contaminated by deposition of a dust such as swarf and the like, and picking up a chip without causing cracking or chipping in the chip after a dicing step, in the steps of dicing the wafer and then picking up the chip. The method includes: sticking the surface protection sheet for dicing onto the surface of the wafer; cutting the sheet together with the wafer; subsequently giving a stimulus to the surface protection sheet for dicing to peel the end of the chip from the dicing tape; and then picking up the chip.

### BACKGROUND OF THE INVENTION

1. Field of the Invention

The present invention relates to a processing method for dicing a semiconductor wafer into individual chips.

2. Description of the Related Art

In a step of dicing a wafer into individual chips (hereinafter referred to as dicing step), which is conducted after a back grinding step, a circuit-formed face of a wafer is conventionally bared. Accordingly, it has been the premise that cutting water in dicing, a dust such as swarf produced by wafer cutting and the like deposit on the circuit-formed face, and the exposed circuit-formed face on the surface of an electronic component is contaminated. The electronic component can cause a defect due to such a contamination. In this case, it is considered to protect the electronic component from the dust such as the swarf and the like by sticking a protection tape onto the circuit-formed face of the wafer, and collectively dicing the wafer and the protection tape. However, it is difficult for a conventional protection tape to be individually peeled and removed from the individual diced wafers, and the collective dicing does not come to be practically used.

Furthermore, in recent years, the semiconductor wafer has progressively been thinned (50 nm or less). The reason includes the purposes of enhancing a radiation performance of a device after having been prepared by using a semiconductor wafer, enhancing the electric characteristics, lowering the consumption of an electric power, and reducing the size of the wafer. In a (back grinding) step of grinding and polishing the semiconductor wafer, a grinding protection tape (back grinding tape) is generally used. The back grinding tape is used when grinding the back surface of the semiconductor wafer to thin the semiconductor wafer after having protected the surface of a pattern of the semiconductor wafer and also while holding the semiconductor wafer.

The thinly ground semiconductor wafer is placed on a dicing tape and is temporarily fixed, the back grinding tape is peeled therefrom, and then the semiconductor wafer is cut into small pieces. In order to collect the chips of the semiconductor wafer converted to small pieces, the chips need to be peeled off (picked up) from the dicing tape. Various peeling methods are proposed, but the most representative method is a method of picking the rear surface of the dicing tape with a needle. A general method of pushing the chip up with the needle can facilitate the peeling of the chip by increasing the pushing up height of the needle. However, in the case of a thin silicon wafer chip, when the needle excessively highly pushes up the chip, the chip may be broken occasionally, which results in lowering the reliability and the yield of the chip.

Japanese Patent Laid-Open No. 2003-197567 describes a method of heating a chip after a dicing operation to thermally shrink the dicing protection tape, and thereby facilitating the removal of the dicing protection tape from the surface of the chip.

In this method, the dicing protection tape is deformed to become random shapes such as wrinkles by the thermal shrinkage. As a result, the dicing protection tape results in forming fine gaps between the salient parts of the unevenness of the wrinkles and the substrate, but neither works for lifting up the semiconductor chip even slightly from the dicing tape which adheres to its lower layer, nor solves the problem of the occurrence of the above described crack in the chip and the like, because the dicing protection tape has been peeled before the picking up step for the diced wafer.

Then, in order to solve the problem of the crack of the chip, Japanese Patent Laid-Open No. 2001-217212 proposes the method, as a method of manufacturing a semiconductor chip, which includes the steps of: fixing the back surface of the semiconductor wafer having a circuit formed on the surface with a dicing tape; bonding a double-faced adhesive sheet which is made from a shrinkable substrate and a tackiness agent layer provided on both surfaces of the substrate, and of which at least one tackiness agent layer is made from an energy beam curing type tackiness agent, onto the circuit surface, cutting and separating the double-faced adhesive sheet and the semiconductor wafer in the state, and dicing the semiconductor wafer according to each circuit to form semiconductor chips; fixing the semiconductor chips onto a transparent hard sheet through the other tackiness agent layer of the double-faced adhesive sheet; and subsequently peeling and removing the dicing tape, irradiating the double-faced adhesive sheet with an energy beam from the above described transparent hard sheet side to thermally shrink the substrate of the double-faced adhesive sheet, and then picking up the semiconductor chips.

However, this method has a defect of needing a more number of steps than the steps of dicing and picking up in a conventional method.

As described above, a problem of the conventional methods is that it may be difficult for these methods to obtain chips which have been converted to small pieces with a picking up operation without increasing the number of the steps and the occurrence of the crack in the chip, depending on conditions of the material of the wafer, particularly the reduced thickness and the like, because the chip is picked up after the dicing protection tape has been peeled off.

Particularly, the dicing tape has the property of being capable of fixing the wafer with sufficient adhesive strength so as to be capable of preventing the crack, the chipping, the movement and the like of the wafer during dicing. When the wafer is thinned, further strong adhesive strength is required. Therefore, when the chip obtained by dicing is picked up, a force against the strong tack force needs to be imparted, regardless of whether the dicing protection film adheres onto the small piece or not. However, if the picking up condition is set so as to impart such a force, the picking up operation may further cause the crack and chipping of the chip, and may lower the line speed and the yield of a manufacturing process.

An object of the present invention is to provide a method including: previously sticking a surface protection sheet for dicing onto the surface of a wafer; collectively cutting the surface protection sheet together with the wafer in a dicing step; thereby protecting the surface of the wafer from being contaminated by deposition of a dust such as swarf and the like; and then surely picking up the wafer without cracking the wafer in a dicing step of obtaining the wafer having been converted to small pieces, in other words, chips, and to enhance the yield by preventing a thereby cut protection tape from contaminating the wafer, a dicing tape and a dicing ring.

### SUMMARY OF THE INVENTION

The means for solving the above described problem is as follows.

The method includes sticking a surface protection sheet for dicing onto a semiconductor wafer, also sticking a dicing tape onto the back surface side of the wafer, and then cutting the wafer together with the surface protection sheet for dicing into small pieces to form chips, wherein one part of the chip is peeled off from the dicing tape by a shrinking stress which has been generated by a stimulus given to the surface protection sheet for dicing, and then the chip is peeled off from the dicing tape.

The surface protection sheet for dicing includes a heat-shrinkable film for at least one layer, and a heat-shrinkable film may be used which shows a thermal shrinkage rate of 3 to 90% in the temperature range of 40 to 180° C.; a surface protection sheet for dicing may also be used which has a tack force of 0.01 N/20 mm or more when heated at 40 to 75° C. (90° peel peeling test with respect to the silicon wafer at a pulling rate of 300 mm/min) and the back surface side of the wafer may also be polished or etched so as to have a predetermined thickness before the dicing tape is stuck thereto.

The surface protection sheet for dicing to be used in the present invention has the property of spontaneously winding by a stimulus such as heating, in a state of being made to adhere to nothing.

The method according to the present invention controls the adhesive force of the surface protection sheet for dicing with respect to the wafer so as to be stronger than a winding force of the surface protection sheet for dicing caused by the stimulus, when sticking such a surface protection sheet for dicing onto the surface of the wafer, collectively cutting the surface protection sheet together with the wafer and then picking up the chip.

Furthermore, when the adhesive force working between the dicing protection tape and the chip is made to be stronger than the adhesive force working between the dicing tape and the chip at the end of the chip, the winding force, in other words, a warping force of the dicing protection tape is transmitted to the cut chip, and the edge of the dicing protection tape which has been cut together with the chip is deformed so as to warp in the winding direction.

As a result of the deformation, the chip decreases the adhesion area between the chip and the adhesive agent layer surface of the dicing tape compared to that before the deformation, and decrease in the adhesion area also lowers the adhesive force between the wafer and the dicing tape.

Then, the decrease in the adhesion area results in being capable of reducing a force necessary for picking up the chip to peel the chip from the dicing tape, which means that a force to be applied to the chip also decreases. The decrease consequently enables the push-up height of the needle to be lowered, and also enables a force to be applied to the chip due to the push-up of the needle to be decreased. As a result, the method shows an effect of causing no crack and no chipping in the chip.

Besides, in the case where the whole surface of the lower surface of the chip adheres to the dicing tape, in order to push up the chip with the needle to peel the chip, it is necessary to firstly peel the end of the chip from the dicing tape, in the dicing tape which adheres even to the end of the chip.

Not only in the case of the chip, in order to peel the substance of which the whole face adheres to some substance, a large force is necessary when forming an initiation site of peeling. Accordingly, also when the chip is peeled, a large force is necessary at first for peeling the end of the chip from the dicing tape by the push-up of the needle.

According to the method of the present invention, the end of the chip is already peeled off from the dicing tape before the chip is firstly pushed up by the needle, and accordingly the peeled portion already becomes an initiation site of peeling, which facilitates the chip to be peeled on the basis of the initiation site of peeling in the push-up step.

### BRIEF DESCRIPTION OF THE DRAWINGS

FIG. 1 is a schematic view illustrating a processing method according to the present invention;

FIG. 2 is a sectional view illustrating a surface protection sheet for dicing and a chip, in a processing method according to the present invention;

FIG. 3 is a sectional view of such a state that the surface protection sheet for dicing and the chip are warped in FIG. 2;

FIG. 4 is a sectional view illustrating one example of the surface protection sheet for dicing to be used in the present invention;

FIG. 5 is a view illustrating another example of the surface protection sheet for dicing to be used in the present invention; and

FIG. 6 is a schematic view illustrating one example of such a state that the surface protection sheet for dicing to be used in the present invention spontaneously winds.

### REFERENCE SIGNS LIST

1 Surface protection sheet for dicing/chip after dicing
2 Wafer
3 Dicing tape
4 Dicing ring
5 Needle
6 Collet
7 Portion from which chip has been taken out
8 Groove
9 Edge
10 Shrinkable film layer
11 Constraining layer
12 Elastic Layer
13 Rigid film Layer
14 Tackiness agent layer
15 Intermediate layer

### DETAILED DESCRIPTION OF THE PREFERRED EMBODIMENTS

The processing method of the present invention is a method including: sticking a surface protection sheet for dicing onto a semiconductor wafer; also sticking a dicing tape onto the back surface side of the wafer; and then cutting the wafer together with the surface protection sheet for dicing into small pieces to form chips, wherein the surface protection sheet for dicing generates a shrinking stress by a stimulus and thereby one part of the chip is peeled from the dicing tape.

Materials necessary for implementing the present invention and a specific processing method will be described below.

### [Wafer]

A wafer to be used in the present invention includes the whole of conventional objects of a dicing step, such as a semiconductor wafer, a glass, a ceramic and a resin for sealing a semiconductor, and preferably includes a semiconductor wafer such as an 8-inch silicon mirror wafer. The size of the wafer after having been cut is arbitrary, but is preferably 10 mm×10 mm or less.

### [Surface Protection Sheet for Dicing]

The surface protection sheet for dicing has a tackiness agent layer formed on one surface of a heat-shrinkable film, and the substrate may be a heat-shrinkable film formed by uniaxially or biaxially stretching a known monolayer or multilayer resin film.

The above described heat-shrinkable film includes, for instance, a uniaxially stretched film or a biaxially stretched film made from one or more resins selected from: a polyester such as polyethylene terephthalate; a polyolefin such as polyethylene and polypropylene; polynorbornene; a polyimide; a polyamide; a polyurethane; polystyrene; polyvinylidene chloride; polyvinyl chloride; and the like. Among the films, a uniaxially stretched film or a biaxially stretched film made from the polyester-based resin, the polyolefin such as polyethylene and polypropylene, the polynorbornene and the polyurethane-based resin is preferable because the coating workability of the tackiness agent layer is excellent.

At least one layer of the heat-shrinkable film to be used for the surface protection sheet for dicing preferably has a thermal shrinkage rate of 3 to 90% in the temperature range of 40 to 180° C., more preferably of 5 to 90%, further preferably of 10 to 90%, and most preferably of 20 to 90%. When the thermal shrinkage rate is less than 3%, the amount of the shrinkage of the heat-shrinkable film is insufficient, the edge of the chip does not come to be peeled, and the chip cannot be picked up. In addition, when the thermal shrinkage rate is more than 90%, the amount of the thermal shrinkage is too large, and the chip is possibly damaged.

The surface protection sheet for dicing is preferably a sheet which has a shrinkable film layer having shrinkability in at least one axial direction, a constraining layer which constrains the shrinkage of the shrinkable film layer and a tackiness agent layer laminated, and spontaneously warp toward one direction from one end or toward the center from opposing two ends by an imparted stimulus which becomes the cause of the shrinkage to be capable of peeling the end of the chip from the dicing tape.

The above described constraining layer is constituted by an elastic layer in a shrinkable film layer side and a rigid film layer in the opposite side of the shrinkable film layer. The surface protection sheet for dicing according to the present invention has also a tackiness agent layer. The tackiness agent layer preferably contains an active energy beam (UV rays, for instance) curable tackiness agent.

The usable laminated body of the shrinkable film layer/constraining layer preferably includes a laminated body of shrinkable film layer/elastic layer/rigid film layer/tackiness agent layer (which may be referred to as spontaneously winding tape hereinafter). The configuration converts a shrinkage stress to a couple, and the tape is deformed to surely become a cylindrical wound body after a stimulus which becomes the cause of the shrinkage has been imparted. For information, as for usable materials and the like which constitute the tape, the details are described in Japanese Patent No. 4151850. Specifically, the tape is preferably a spontaneously winding tape which is a laminated body made of shrinkable film layer/elastic layer/rigid film layer/tackiness agent layer. The stimulus for shrinking the tape is preferably heating.

A tackiness agent for the tackiness agent layer provided on the surface protection sheet for dicing may be a known rubber-based tackiness agent, a known acrylic tackiness agent and the like which contain a known filler and various known additives; and can employ also a known tackiness agent which is cured by the formation of a three-dimensional network structure by irradiation with an active energy beam such as ultraviolet rays and consequently lowers its tack force to make the protection sheet easily peelable. The tackiness agent can employ a tackiness agent composition including: a rubber-based tackiness agent which uses a rubber-based polymer such as a known natural rubber, a polyisobutylene rubber, a styrene/butadiene rubber, a styrene/isoprene/styrene block copolymer rubber, a reclaimed rubber, a butyl rubber and NBR as a base polymer, and is blended with various well-known additives; a silicone-based tackiness agent; and an acrylic tackiness agent; the above tackiness agent composition that is formed by chemically modifying a resin constituting the tackiness agents with a reactive group containing a carbon-carbon multiple bond; and the above tackiness agent composition that is further blended with a monomer or a polymer which have a reactive group such as a poly(meth)acryloyl group. The tackiness agent can also employ the following tackiness agent for a dicing tape.

The surface protection sheet for dicing preferably has a tack force (90° peel peeling test with respect to the silicon mirror wafer at a pulling rate of 300 mm/min) of 0.01 N/20 mm or more in an atmosphere at 40 to 75° C., more preferably of 0.02 N/20 mm or more, further preferably of 0.03 N/20 mm or more, and most preferably of 0.05 N/20 mm or more. If the tack force is less than 0.01 N/20 mm, when the wafer is placed in the atmosphere at the predetermined temperature, the surface protection sheet for dicing is peeled, and the chip cannot be picked up by a low push-up height.

The thickness of the tackiness agent layer is generally 10 to 200 μm, preferably is 20 to 100 μm, and further preferably is 30 to 60 μm. When the above described thickness is too thin, the tack force is insufficient and accordingly it tends to be difficult to hold and temporally fix an adherend. When the thickness is too thick, the tackiness agent layer is not preferable because of being uneconomical and being inferior also in handleability.

In the range having the above described tack characteristics, the substrate of the surface protection sheet for dicing needs to be shrunk by a stimulus and the like.

The stimulus is a treatment by energy-imparting means such as heating and ultraviolet ray irradiation necessary for shrinking the adhered surface protection sheet for dicing. Specifically such means can be used as arbitrary heating means like spouting of a heated air, immersion into a liquid such as a heated water, an infrared lamp, an infrared laser, an infrared LED, a plate heater, a band heater, a ribbon heater and the like, and irradiation means like an ultraviolet lamp, a microwave, and the like. The heating temperature is a temperature which does not exert a bad influence on the characteristics of the wafer, and is a temperature of 40° C. or higher, preferably of 50° C. to 180° C., and further preferably of 70 to 180° C. The irradiation with the ultraviolet lamp or the microwave has an irradiation energy amount also similarly in such a range that the irradiation does not exert the bad influence on the characteristics of the wafer, and is to conduct a treatment in such a level that the irradiation warps the surface protection sheet for dicing and the chip by shrinking particularly a heat-shrinkable film layer of the surface protection sheet for dicing. For information, when the above described means of the immersion into the heated water or the like is adopted, a step using well-known drying means for drying is needed afterward.

The adhesive forces between the surface protection sheet for dicing and the wafer and between the wafer and the dicing tape are adjusted so that the surface protection sheet for dicing is not peeled from the chip even by the shrinkage of the surface protection sheet for dicing by the stimulus and only the end of the chip is peeled from the dicing tape. For the purpose, the chip needs to adhere to the dicing tape with a strength of such a level that only the end is permitted to be peeled.

In addition, these surface protection sheets for dicing preferably have a shrinkable film layer having shrinking properties in at least one axial direction, and a constraining layer which constrains the shrinkage of the shrinkable film layer laminated. A single surface protection sheet for dicing spontaneously winds toward the center from the opposing two ends by the imparted stimulus which becomes the cause of the shrinkage, and forms one piece of a cylindrical wound body.

In some cases, it is necessary to lower the adhesive force of the surface protection sheet for dicing with respect to the chip after the chip has been picked up.

At this time, it is possible to use: a known tackiness agent which is cured by the formation of a three-dimensional network structure by the irradiation with an active energy beam such as ultraviolet rays, and consequently lowers the tack force to make the protection sheet easily peelable; a tackiness agent containing a gas-generating agent, which contains, in a tackiness agent layer, a gas-generating agent such as an azide compound and an azide, decomposes the gas-generating agent by heating after the chip has been picked up to generate a gas, converts the tackiness agent layer into a porous layer to make the tackiness agent layer and its surface uneven, reduces the adhesion area between the tackiness agent layer and the chip to develop easy-peelability; a tackiness agent containing gas-containing microcapsules, which contains gas-containing microcapsules, destroys the microcapsules by heating them during use, makes the contained gas spread into the tackiness agent layer to convert the tackiness agent layer to a porous layer, and develops easy-peelability, with a similar mechanism to that in the above described surface protection sheet containing the gas-generating agent for dicing; or the like.

### [Dicing Tape]

The dicing tape is formed of a substrate layer, a tackiness agent layer for adhering the substrate layer to a wafer, and an adhesive agent layer on the opposite surface in which the circuit of the wafer is not formed, as needed.

The tackiness agent layer bonds and fixes the wafer for preventing the chip from spreading when the wafer is diced into small pieces of a chip shape, and accordingly has a sufficient adhesive force. Furthermore, the tackiness agent layer functions as a tackiness agent layer for fixing the chip when having mounted the chip onto the substrate, as needed.

The substrate layer can employ a known substrate layer as a substrate layer for a dicing tape. The substrate layer includes for instance: a polyolefin such as polyethylene, polypropylene, polybutene and polymethylpentene; an ethylene-vinylacetate copolymer; an ionomer resin; an ethylene-(meth)acrylic acid copolymer; an ethylene-(meth)acrylate copolymer; an ethylene-butene copolymer; an ethylene-hexene copolymer; a polyester such as polyurethane, polyethylene terephthalate, polyethylene naphthalate and polybutylene terephthalate; polycarbonate; polyimide; polyether ether ketone; polyether imide; polyamide; wholly aromatic polyamide; polyphenyl sulfide; polycarbonate; aramid; paper; glass; a glass cloth; a fluorine resin; polyvinyl chloride; polyvinylidene chloride; a cellulose-based resin; a silicone resin; and a metal (foil). The substrate layer also includes a polymer such as crosslinked bodies of the above described resins.

The thickness of the substrate layer is not limited in particular, and may be in a range, for instance, of 5 to 300 μm, preferably of 25 to 200 μm, and more preferably of 35 to 200 μm, in consideration of the workability in a dicing step, the cut by a dicing blade and the like.

For the purpose of enhancing the firm adhesion to the tackiness agent layer, the surface of the substrate layer may be subjected to a known surface treatment, for instance, an oxidation treatment by a chemical or physical method and the like such as chromate treatment, ozone exposure, flame exposure, high-pressure electrical shock exposure and ionized radioactive ray treatment, and may also be subjected to a coating treatment and the like by an undercoating agent, an anchor coating agent such as an isocyanate-based anchor agent, or the like.

The tackiness agent layer can be formed of a normal adhesive agent for a dicing tape. Among such adhesive agents, this adhesive agent is preferably formed into a sheet shape. For instance, a tackiness agent made from a thermoplastic resin or a thermosetting resin can be preferably used, and can be used singly or in combinations of one or more. The tackiness agent layer also can stick to a wafer preferably at 70° C. or lower, and more preferably stick to the wafer further at a normal temperature.

The tack force is 0.5 N/20 mm or less with respect to the silicon mirror wafer at room temperature, and preferably is 0.3 N/20 mm or less. When the tack force is 0.5 N/20 mm or less, the peelability becomes adequate, and the occurrence of a residual glue can be reduced. The value of the tack force of the tackiness agent layer can be increased or decreased in the above described range according to the intended use and the like.

A thermoplastic resin to be used as a tackiness agent includes, for instance, a rubber-based resin, an acrylic resin, a saturated polyester resin, a thermoplastic-polyurethane-based resin, an amide-based resin, an imide-based resin and a silicone-based resin. In addition, a thermosetting resin includes, for instance, an epoxy resin, an unsaturated-polyester-based resin, a thermosetting acrylic resin and a phenol-based resin. As for the thermosetting resin, a thermosetting resin formed by being desolvated, sheeted and B-staged (temporary cured) is preferable. In addition, the mixture of these thermosetting resins and thermoplastic resins can also be used in a state of having been B-staged. Here, the acrylic-resin-based tackiness agent which employs an acrylic resin as a base polymer is preferable from the viewpoint of efficiency in cleaning an electronic component which dislikes the contamination of the wafer, the glass and the like with ultrapure water or an organic solvent such as alcohol.

The above described acrylic resin includes, for instance, an acrylic polymer which uses one or more types of cycloalkyl(meth)acrylates as a monomer component containing an alkyl group having 1 to 30 carbon atoms, and particularly a straight chain or branched chain alkyl group having 4 to 18 carbon atoms.

The tackiness agent layer may have a multilayer structure of two or more layers by appropriately combining thermoplastic resins having different glass transition temperatures and thermosetting resins having different thermosetting temperatures. For information, in the dicing step of the wafer, cutting water is used, and accordingly the tackiness agent layer absorbs water to reach a water content of a normal state or more in some cases. If the tackiness agent layer is adhered to the substrate and the like in a state of such a high water content, water vapor gathers in the adhesion interface in the stage of postcure, and lifting occurs in some cases. Accordingly, when the tackiness agent layer has a configuration in which a film having high permeability is sandwiched between the tackiness agent layers, water vapor diffuses through the film in the stage of the postcure, which enables such a problem to be avoided. Accordingly, the tackiness agent layer may have a multilayer structure of having the tackiness agent layer, the film and the tackiness agent layer laminated in this order.

The thickness of the tackiness agent layer is not limited in particular, but preferably is approximately 5 to 100 μm, for instance, and more preferably is approximately 10 to 50 μm.

The above described acrylic resin may also contain a unit corresponding to other monomer components which are copolymerizable with the above described an alkyl (meth)acrylate or a cycloalkyl (meth)acrylate, as needed, for the purpose of modifying a cohesive force, heat resistance and the like. Such a monomer component includes, for instance: a carboxyl-group-containing monomer such as acrylic acid, methacrylic acid, a carboxyethyl (meth)acrylate, a carboxypentyl (meth)acrylate, itaconic acid, maleic acid, fumaric acid and crotonic acid; an acid anhydride monomer such as maleic anhydride and itaconic acid anhydride; a monomer containing a hydroxyl group such as 2-hydroxyethyl (meth)acrylate and 2-hydroxypropyl (meth)acrylate; a monomer containing a sulfonic acid group such as styrene sulfonate; a monomer containing a phosphoric acid group such as 2-hydroxyethyl acryloyl phosphate; acrylamide; and acrylonitrile. These copolymerizable monomer components can be used solely or with other one or two types of monomer components. The amount of these copolymerizable monomers to be used is preferably 40 wt % or less of all monomer components.

Furthermore, the above described acrylic resin can contain also a polyfunctional monomer and the like for crosslinking as a monomer component for copolymerization, as needed. Such a polyfunctional monomer includes, for instance, hexanediol di(meth)acrylate and (poly)ethyleneglycol di(meth)acrylate. These polyfunctional monomers also can be used solely or with other one or more types of polyfunctional monomers. The amount of the polyfunctional monomer to be used is preferably 30 wt % or less of the total monomer component from the viewpoint of tack characteristics. In addition, an external crosslinking agent such as a polyisocyanate compound, an epoxy compound, an aziridine compound and a melamine-based crosslinking agent can also be added.

The radiation curing type tackiness agent which works as the tackiness agent can employ a tackiness agent which has a radiation curable functional group such as a carbon-carbon double bond and shows tackiness, without being particularly limited, and specifically can adopt an addition type of a radiation curable tackiness agent and the like, which is formed by blending a radiation curable monomer component and oligomer component to a general pressure sensitive tackiness agent such as the above described acrylic tackiness agent and the rubber-based tackiness agent.

By adopting the radiation curable tackiness agent, it becomes possible to crosslink the tackiness agent layer by irradiating the tackiness agent with radioactive rays before picking up the chip to lower the adhesive force, and thereby to further decrease the push-up amount of a needle.

The radiation curable monomer component to be blended includes, for instance, a urethane oligomer, urethane (meth)acrylate and trimethylol propane tri(meth)acrylate. The radiation curable oligomer component includes various oligomers such as a urethane-based oligomer, a polyether-based oligomer, a polyester-based oligomer, a polycarbonate-based oligomer and a polybutadiene-based oligomer, and has suitably a molecular weight in the range of approximately 100 to 30,000. As for the amount of the radiation curable monomer component or oligomer component to be blended, the amount by which the tack force of the tackiness agent layer can be lowered can be appropriately determined according to a type of the above described tackiness agent layer. Generally, the amount is, for instance, 5 to 500 parts by weight with respect to 100 parts by weight of the base polymer such as an acrylic polymer constituting the tackiness agent, and preferably is approximately 40 to 150 parts by weight.

The radiation curing type tackiness agent also includes an endogenous radiation curable tackiness agent which uses a tackiness agent having a carbon-carbon double bond in a polymer side chain, in a main chain or in the end of the main chain, as a base polymer, in addition to the above described addition type radiation curable tackiness agent. The endogenous radiation curable tackiness agent does not need to contain an oligomer component and the like, which is a low molecular component, or does not contain the oligomer component so much, and accordingly can form the tackiness agent layer having a stable layer structure because the oligomer component and the like do not move in the tackiness agent with time, which is preferable.

The above described base polymer having the carbon-carbon double bond can employ a base polymer which has a carbon-carbon double bond and has tackiness, without being particularly limited. Such a base polymer is preferably a polymer which contains an acrylic polymer as a basic skeleton. The basic skeleton of the acrylic resin includes the above described illustrated acrylic resin.

A method of introducing the carbon-carbon double bond into the above described acrylic resin is not limited in particular, and can adopt various methods. The carbon-carbon double bond is more easily introduced into a polymer side chain from the viewpoint of a molecular design. The introduction method includes, for instance, a method of previously copolymerizing a monomer having a functional group with an acrylic resin, and then subjecting the resultant product and a compound which has a functional group that can react with the functional group and has a carbon-carbon double bond, to a condensation or addition reaction while maintaining the radiation curability of the carbon-carbon double bond.

An example of the combination of these functional groups includes: a carboxylic acid group and an epoxy group; a carboxylic acid group and an aziridyl group; and a hydroxyl group and an isocyanate group. Among these combinations of the functional groups, the combination of the hydroxyl group and the isocyanate group is preferable because the reaction is easily pursued. In addition, the functional group may be in any side of the acrylic polymer and the above described compound as long as the combination is such a combination that the acrylic polymer having the above described carbon-carbon double bond is produced by the combination of these functional groups, but it is preferable in the case of the above described preferable combination that the acrylic polymer has a hydroxyl group and the above described compound has an isocyanate group. In this case, the isocyanate compound having the carbon-carbon double bond includes, for instance, methacryloyl isocyanate, 2-methacryloyloxyethyl isocyanate, and m-isopropenyl-α,α-dimethylbenzyl isocyanate. In addition, a usable acrylic polymer includes a polymer obtained by copolymerizing the above described illustrated monomer containing the hydroxyl group, and an ether-based compound such as 2-hydroxyethyl vinyl ether, 4-hydroxybutyl vinyl ether and diethylene glycol monovinyl ether.

The radiation curable tackiness agent can use the base polymer (particularly acrylic polymer) having the above described carbon-carbon double bond solely, but can also be blended with the above described radiation curable monomer component or oligomer component in a level which does not to aggravate the characteristics. The radiation curable oligomer component and the like is normally in the range of 30 parts by weight with respect to 100 parts by weight of the base polymer, and preferably is in the range of 0 to 10 parts by weight.

When the above described radiation curing type tackiness agent is cured by ultraviolet rays and the like, a photopolymerization initiator is made to be contained in the tackiness agent. The photopolymerization initiator includes, for instance, a ketal-based compound such as 4-(2-hydroxyethoxy)phenyl(2-hydroxy-2-propyl) ketone; an aromatic sulfonyl chloride-based compound such as 2-naphthalene sulfonyl chloride; a photoactive oxime-based compound such as 1-phenon-1,1-propanedione-2-(o-ethoxycarbonyl) oxime; a benzophenone-based compound such as benzophenone, benzoylbenzoic acid and 3,3′-dimethyl-4-methoxybenzophenone; a thioxanthone-based compound such as thioxanthone and 2-chloro thioxanthone; camphorquinone; a halogenated ketone; acyl phosphine oxide; and acyl phosphonate. The amount of the photopolymerization initiator to be blended is, for instance, approximately 0.05 to 20 parts by weight with respect to 100 parts by weight of the base polymer constituting the tackiness agent such as the acrylic polymer.

The radiation curing type tackiness agent also includes, for instance, a rubber-based tackiness agent, an acrylic tackiness agent and the like which contain a photopolymerizable compound such as an addition-polymerizable compound having unsaturated bonds in two or more sites and an alkoxysilane having an epoxy group, and a photopolymerization initiator such as a carbonyl compound, an organosulfur compound, a peroxide, an amine and an onium-salt-based compound.

### [Method for Processing Wafer According to Present Invention]

The method according to the present invention includes the steps of: sticking a surface protection sheet for dicing to a wafer; sticking a dicing tape to the back surface side of the wafer; cutting the wafer together with the surface protection sheet for dicing into chips; stimulating the surface protection sheet for dicing to generate a shrinkage stress therein, and peeling the surface protection sheet for dicing and the end of the chip from the dicing tape; and pushing up a needle from the lower part of the dicing tape, and thereby peeling the chip from the dicing tape.

### [Step of Sticking Surface Protection Sheet for Dicing]

The step includes making a face of the tackiness agent layer of the above described surface protection sheet for dicing firmly adhere to and be fixed to the circuit-formed face of the wafer which has been mounted on a table, by making the face of the tackiness agent layer oppose to and be brought into contact with the surface of the wafer, and by pressing the surface protection sheet for dicing from the back face side thereof with a pressing roller and the like. In the pressing step, it has been described that the surface protection sheet is pressed by the pressing roller, but it is also possible to mount the wafer in a pressurizable container, provide the surface protection sheet for dicing on the circuit-formed face thereof, and then pressurize the inside of the container to make the surface protection sheet adhere to the wafer.

For information, this sticking step is normally conducted after a back grinding step, but may be conducted before the back grinding step. When the step is conducted before the back grinding step, the surface protection sheet for dicing also functions as a back grinding tape.

### [Step of Sticking Dicing Tape]

Similarly to the above described step of sticking the surface protection sheet for dicing, the step includes: making a face of the tackiness agent layer of the above described dicing tape firmly adhere to and be fixed to the back surface of the wafer, by making the face of the tackiness agent layer oppose to and be brought into contact with the back surface of the wafer, and by pressing the dicing tape from the back face side thereof with a pressing roller or the like, or by pressurizing the inside of the pressurizing container.

### [Dicing Step]

In the present invention, this surface protection sheet for dicing is affixed onto an adherend, and then the resultant product is diced. The dicing apparatus and method may arbitrarily select and adopt a known method such as a blade dicing method and a laser dicing method, can also adopt a step of concomitantly using a step of spouting water or gas to the portion to be cut during dicing, and are not limited by using the surface protection sheet for dicing.

Here, when the adherend is a semiconductor wafer, it is also acceptable to affix the surface protection sheet for dicing onto the adherend, then subjecting the resultant product to the back grinding step, affixing the dicing tape on the resultant product in the state, without peeling the surface protection sheet for dicing therefrom, and subjecting the resultant product to the dicing step.

### [Step of Peeling End of Wafer]

After having been diced, the cut surface protection sheet for dicing shrinks by being stimulated and generates a force to wind. The force to wind this surface protection sheet for dicing generates a force which warps the end of the surface protection sheet for dicing toward the upper part, particularly on the end of the chip, and the force works as a force which warps even also the end of the chip to which the end of the surface protection sheet for dicing adheres toward the upper part, and is transmitted to the end of the chip.

As a result, the end of the chip is peeled from the tackiness agent layer on the dicing tape to which the lower part of the chip adheres, and similarly warps toward the upper part. As a result, the chip makes the adhesion area with respect to the dicing tape decrease, in other words, results in making the adhesive force also decrease.

Furthermore, as a result of the peeling of the end of the chip, the peeled portion becomes an initiation site of peeling in a picking up step, and accordingly when the chip is pushed up by a needle, the peeling of the chip results in further smoothly proceeding while starting from the initiation site of peeling.

Among the stimuli, the stimulus by heating can be carried out by adopting a known heating method such as a hot plate, a heater, a heat gun and an infrared lamp as a heat source.

An appropriate method is selected and used so that the temperature of the surface protection sheet for dicing can reach a temperature at which the surface protection sheet for dicing quickly deforms. The heating temperature is not limited in particular, for instance, as long as the upper limit temperature is a temperature at which the wafer winds without being affected, but is, for instance, 40° C. or higher, preferably is 50° C. to 180° C., and further preferably is 70° C. to 180° C. The stimulus which becomes the cause of shrinkage may be uniformly imparted to the whole surface protection sheet for dicing to deform the whole surface protection sheet at a time, and in addition, may also be imparted to one part of the wafer in a spot form. The stimulus may also be imparted, for instance, by a method of partially heating an arbitrary position by using a spot-heating device and the like to deform the surface protection sheet of the position.

When shrinking the surface protection sheet for dicing by the stimulus due to ultraviolet rays, it is acceptable to use a high-pressure mercury lamp, a xenon lamp, an ultraviolet LED and the like of a conventionally known method as a light source, for means of emitting the ultraviolet rays, and irradiating the surface protection sheet for dicing with the ultraviolet rays having approximately 500 to 1,000 mJ/cm².

### [Picking Up Step]

The method according to the present invention is a method of lowering the height of the pushing up needle, thereby decreasing a force applied to the chip, and preventing the crack of the chip, in the picking up step for the chip.

Before the picking up step, an expanding step with the use of an expanding device may occasionally be conducted. In addition, the step of imparting the stimulus to the surface protection sheet for dicing may be conducted before the step of peeling the chip from the dicing tape, or may be conducted at the same time. When a collet for adsorbing the chip is used, it is desirable that the abutting portion of the collet does not cover the end of the chip.

The method and the apparatus to be used in the picking up step are not limited in particular, and can adopt known means of pushing up the needle having an arbitrary diameter and shape from the dicing tape side of the chip thereby to peel the chip, and picking up the chip with a picking up device and the like.

Embodiments of the present invention will be described below with reference to the drawings.

FIG. 1 is a schematic view illustrating one example of a peeling method with the use of a surface protection sheet for dicing, which has the property of forming a cylindrical wound body and peels the chip while winding. The embodiments will be described below with reference to FIG. 1.

### <Preparation of Sample for Dicing>

A laminated body is formed, as is illustrated in FIG. 1, by sticking the surface protection sheet for dicing to an adherend such as a wafer. The adherend includes all conventional objects for dicing such as a semiconductor wafer, a glass, a ceramic and a resin for sealing semiconductor. Means for sticking the surface protection sheet for dicing to the adherend such as the wafer is not limited in particular. The surface protection sheet for dicing can be stuck by using a roller, for instance.

A semiconductor wafer such as an 8-inch silicon mirror wafer is preferably used as the adherend. When the semiconductor wafer is used as the adherend, the adherend in the laminated body may be subjected to a treatment such as a back grinding treatment, and may be adjusted so as to have a predetermined thickness. When the adherend is the semiconductor silicon wafer, a silicon wafer having a thickness of several tens μm to several hundreds μm can be used, and a silicon wafer particularly having a thickness as extremely thin as 100 μm or less can also be used.

Next, the adherend side of the laminated body of the surface protection sheet for dicing and the adherend is stuck onto the dicing tape to form a laminated body of the surface protection sheet for dicing, the adherend and the dicing tape, as is illustrated in FIG. 1(A). A usable dicing tape is not limited in particular, and includes a known dicing tape. This laminated body shall be a sample for dicing. This laminated body may also be further stuck onto a dicing ring. A method of sticking the laminated body of the surface protection sheet for dicing, the adherend and the dicing tape onto the dicing ring is not limited in particular, and the laminated body can be stuck by using a roller, for instance.

### <Dicing>

Subsequently, the sample for dicing is diced to be formed into a state as illustrated in FIG. 1(B). The dicing operation can be conducted by using a known dicing device, and can be conducted by using a blade dicing device, a laser dicing device and the like. The dicing operation may be conducted while pouring water. The amount of cutting water is not limited in particular, and can be set at 1 L/min, for instance. The sample is diced into a chip shape of 5 mm×5 mm, 10 mm×10 mm or the like, for instance.

When the blade dicing device is used, the dicing speed and the rotation number of the blade can be arbitrarily set according to the base material, the thickness and the like of the adherend. When the adherend is a silicon wafer, the dicing speed can be set at 10 to 100 mm/sec, for instance, and preferably at 30 to 90 mm/sec; and the rotation number of the blade can be set at 30,000 to 50,000 rpm, and preferably at 35,000 to 45,000 rpm. The blade height can be appropriately and arbitrarily set in the known range.

When the surface protection sheet for dicing to be used in the present invention is stuck onto the adherend, the surface protection sheet for dicing is collectively cut together with the adherend, but the surface protection sheet for dicing is prevented from splashing during dicing by surely being stuck to the adherend.

Such a laminated body of the surface protection sheet for dicing and the adherend shows adequate dicing properties, and can provide a chip formed of the surface protection sheet for dicing laminated on the adherend, without causing the chipping and the crack of the wafer or making water to be used in the dicing operation enter the interface between the surface protection sheet for dicing and the adherend.

<Impartment of Stimulus which Becomes Cause of Shrinkage>

The surface protection sheet for dicing to be used in the method of the present invention has preferably the property of winding when the stimulus which becomes the cause of shrinkage such as heat has been imparted thereto. General means of imparting the stimulus which becomes the cause of the shrinkage is heating, but is not limited to heating. When the stimulus which becomes the cause of the shrinkage, for instance, such as heating, has been imparted to the chip obtained by dicing, the surface protection sheet for dicing deforms to have a warp at the end of the chip so as to draw an arc. The adhesion area between the chip and the dicing tape is smaller after the chip has been warped, in comparison with the case in which the chip is not warped.

Here, the timing of heating for peeling the surface protection sheet for dicing is arbitrary and is not limited in particular, but is as late as possible from the viewpoint of protecting the wafer 2, and is preferably right before the picking up step.

When having deformed such a surface protection sheet for dicing by heating, for instance, it is possible to surely warp the ends of the wafer together with the wafer with adequate reproducibility by selecting predetermined conditions on the heating temperature, the configuration of the surface protection sheet for dicing and the like. The state after the chips have been warped is illustrated in FIG. 1(C).

When the stimulus which becomes the cause of the shrinkage, such as heating, is imparted to the surface protection sheet for dicing, the whole surface of the adherend may be uniformly stimulated, but the whole surface may also be gradually stimulated or partially stimulated, as needed in a peeling operation. The heating temperature and the heating period of time for the surface protection sheet for dicing, for instance, can be appropriately adjusted according to shrinking properties of a heat-shrinkable substrate to be used, and the temperature can be set at a temperature necessary for the end of the surface protection sheet for dicing to warp together with the wafer. The heating period of time is, for instance, approximately 5 to 600 seconds, preferably is approximately 5 to 300 seconds, and more preferably is approximately 5 to 180 seconds.

The heating method is not limited in particular, but can illustrate a heating source such as a hot plate, a heat gun and an infrared lamp. The heating by the hot plate, for instance, results in simultaneously deforming and warping the surface protection sheets for dicing on all of the chips on the hot plate. The heating by the heat gun, for instance, can locally heat the chips, and accordingly can deform only the surface protection sheets for dicing on some chips, as needed.

As for the heating temperature of the surface protection sheet for dicing, the maximum temperature is not limited in particular as long as the end of the wafer can warp together with the surface protection sheet for dicing without being affected by the temperature, but can be set at 40° C. or higher, for instance, preferably at 50° C. to 180° C., and further preferably at 70° C. to 180° C. When the heating temperature is lower than 40° C., the surface protection sheet for dicing cannot be sufficiently deformed or is not quickly deformed. When the heating temperature is too high, a defect such as damage to the adherend occurs.

The size of the diameter r of the arc which is drawn by the wound body that is formed by the sole and spontaneous winding of the surface protection sheet for dicing, which does not adhere to the wafer, can be appropriately adjusted according to heating conditions such as the heating temperature and the amount of the hot air, the composition/configuration of the surface protection sheet for dicing and the like, for instance. In other words, the wound state of the wound body is preferably determined according to conditions such as the heating condition and the configuration of the surface protection sheet for dicing. The smaller the diameter r is, the stronger the degree of winding is. The surface protection sheet for dicing is deformed preferably into a cylindrical wound body by heating. This degree of the deformation is reflected in the degree of a force of warping the end of the wafer when the surface protection sheet for dicing has adhered to the wafer.

Such a wound body is formed originating in a shrinkage stress by heating of the shrinkable substrate, for instance. The development of the shrinkage stress is a thermal irreversible process (process in which the state does not return to the unshrinking state even by reheating), and accordingly the wound body is not spontaneously unwound even by continuously being heated after having been wound once, is not easily unwound also by stress because of the high elasticity of the shrinkage substrate and a rigid substrate after having been heated, and holds the constant shape. For this reason, the wound body is not easily crushed or widened.

It is estimated that in order to unwind the wound body which has been heated, for instance, at 80° C. for approximately 30 seconds, a stress, for instance, of 1.3 N/10 mm or more is needed. In addition, in order to compress the diameter of the wound body having a width of 10 mm to approximately one-third, a load of 250 g to 300 g force is needed, for instance, and when the load has been removed, the diameter of the wound body is returned to an almost initial state. Furthermore, as was described above, the wound state of the wound body can be determined by setting the conditions. An individual chip shows a substantially fixed and same shape according to the conditions.

Here, the surface protection sheet for dicing may include a UV curable tackiness agent. In this case, the surface protection sheet for dicing can be irradiated with UV rays, before or after the impartment of the stimulus which becomes the cause of the shrinkage such as heating for the spontaneous winding of the surface protection sheet 1 for dicing. The surface protection sheet for dicing may be irradiated with UV rays simultaneously with the impartment of the stimulus.

### <Picking Up>

The point of a needle 5 arranged in the lower part of the dicing tape is directed toward a chip to be picked up in such a state that the dicing protection tape and the end of the chip are warped toward the upper part by being diced and by the subsequent impartment of the stimulus such as heating.

The needle is moved to the upper part and pushes up, thereby the point of the needle 5 pushes the dicing tape or intrudes in the dicing tape, and thereby a force of moving the chip adhering to the dicing tape toward the upper part is imparted to the chip.

In such a state that the adhesion area between the chip having warped toward the upper part and the dicing tape becomes small, the dicing tape curves toward the upper part by a pressure of the needle 5, and thereby tends to further reduce the adhesion area.

When the needle 5 is further pushed up, this tendency becomes further remarkable, and the adhesion area between the chip and the dicing tape, in other words, the adhesive force becomes smaller. When the adhesion area becomes small to some extent, a member for holding the chip, for instance, such as a collet 6 is brought into contact with the surface of the surface protection sheet for dicing from the upper part of the chip and the surface protection sheet 1 for dicing, and holds the chip and the surface protection sheet 1 for dicing by suction or the like.

Subsequently, the needle pushes the surface protection sheet for dicing and the chip up to the position and the adhesive force between the chip and the dicing tape, at which the collet 6 can hold the sheet and the chip. The state is illustrated in FIG. 1(D).

Then, the collet 6 moves the surface protection sheet for dicing and the chip to a subsequent processing step such as a step of removing the surface protection sheet for dicing on the surface of the chip, from the dicing tape. The state of having the portion from which the chip has been taken out is illustrated in FIG. 1(E).

The state of FIG. 1(C) will be further described below.

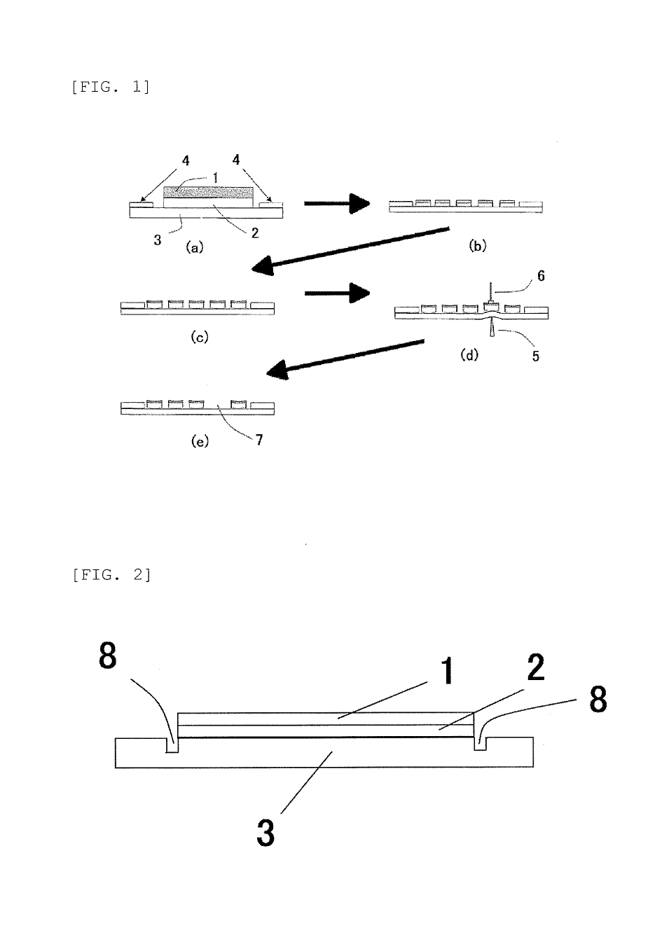

FIG. 2 illustrates the sectional view of a state of one arbitrary chip after the surface protection sheet for dicing has been stuck onto the surface of the wafer, and the wafer has been stuck onto the dicing tape and diced.

The diced surface protection sheet 1 for dicing is laminated on the surface of the individual chip 1, and the laminated body is adhered to the dicing tape 3. A groove 8 is formed in the dicing tape around the chip 1 by the dicing operation.

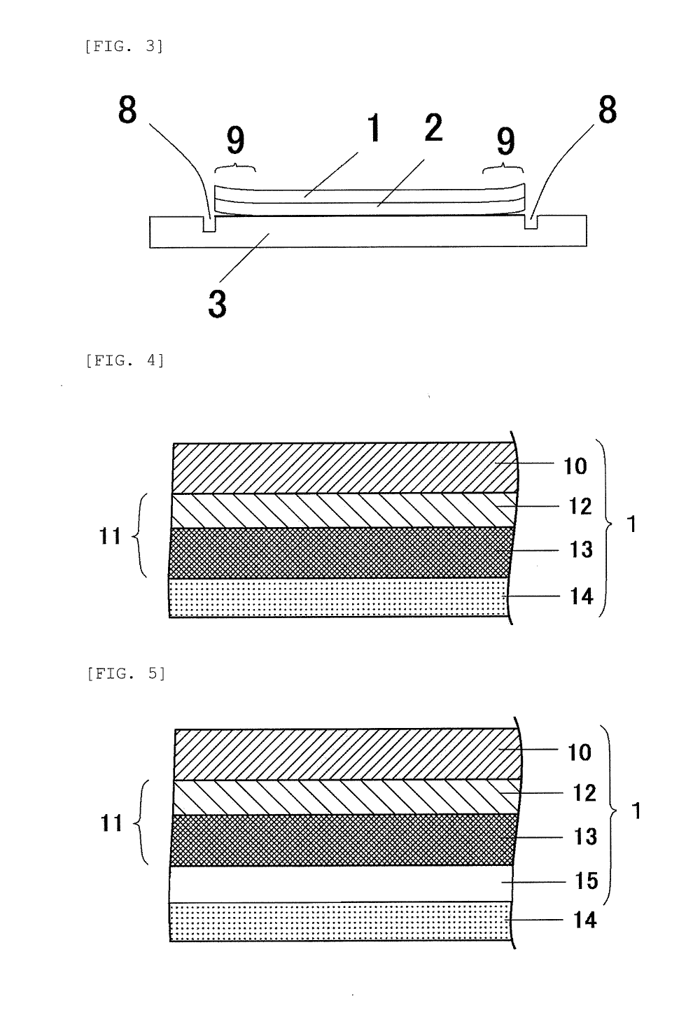

In this structure, the edge of the surface protection sheet for dicing is deformed so as to warp by the stimulus such as heating imparted to the surface protection sheet for dicing, the chip 1 adhering to the surface protection sheet for dicing is similarly deformed along with the above deformation, and the edge results in warping toward the upper part, as is illustrated in FIG. 3. The chip 1 at the edge 9 of the warping portion is peeled from the tackiness agent layer of the dicing tape 3, and constitutes the portion at which the chip does not adhere to the dicing tape 3.

As a result, the chip 1 results in adhering to the dicing tape at only one part of the surface except the edges of the lower surface of the chip after the stimulus such as heating has been imparted, though the chip 1 has adhered to the dicing tape 3 on the whole surface of the lower surface of the chip before the stimulus such as heating is imparted.

Decrease in the adhesion area, consequently, obviously causes decrease in the adhesive force of the chip 1 with respect to the dicing tape 3, and enables the adhesive force to be lowered down to a level which is sufficient for peeling the chip from the dicing tape even by a less push-up amount of the needle.

In addition, not only by the decrease in the adhesion area of the chip and the dicing tape, but also by the initiation site of peeling at which the edge of the chip has been peeled off from the dicing tape, the chip is further facilitated to be peeled from the dicing tape when having been pushed up by the needle.

### <Removal>

A method of removing the surface protection sheet for dicing, which adheres to the surface of the chip after having been picked up, firstly needs to lower the adhesive force of the surface protection sheet for dicing.

For this purpose, the surface protection sheet for dicing is subjected to a treatment of lowering the adhesive force according to properties of the tackiness agent layer, such as heating when the tackiness agent layer of the surface protection sheet for dicing causes foaming and the like by additional heating to lower its adhesive force, and irradiation with an energy beam when the tackiness agent layer is crosslinked by the energy beam such as ultraviolet rays to lower the adhesive force.

Adoptable methods for removing an unnecessary surface protection sheet for dicing after the adhesive force has been sufficiently lowered in this way include: a method of removing the surface protection sheet by bringing an adhesive face of an adhesive sheet for peeling the surface protection sheet for dicing in contact with the surface of the surface protection sheet for dicing; a method of spraying a gas to the surface protection sheet for dicing to blow the surface protection sheet off; a method of sucking the surface protection sheet to remove the surface protection sheet; and a method of picking up the surface protection sheet by using some means for picking up or the like.

In the method of removing the surface protection sheet by bringing the adhesive face of the adhesive sheet in contact with the surface of the surface protection sheet for dicing, an adhesive tape having arbitrary sufficient tackiness can be adopted, and even the known material has sufficient material quality and the like.

The blowing method can remove the surface protection sheet for dicing formed on the adherend, by blowing the surface protection sheet off with the use of a wind power generation medium. The surface protection sheet for dicing in the present invention can be easily removed by wind with a comparative weak power, due to decrease in the adhesive force by heating or the like after the picking up step.

The usable wind power generation medium includes a well-known device such as a blower, a drier and a fan. The removal method by blowing may be conducted with air of ordinary temperature, or may also be conducted with warm air or hot air.

The removal method by blowing may also be conducted while decreasing the adhesive force of the surface protection sheet for dicing by heating or the like. In this case, a hot plate, hot air or the like can be used. The temperature of the hot air can be determined so that the surface temperature of the surface protection sheet 1 for dicing becomes 80° C. to 100° C., for instance.

In the removal method by sucking, a suction medium is used, which removes the surface protection sheet for dicing having the lowered adhesive force on the adherend by sucking the wound body of the surface protection sheet for dicing.

A usable suction medium includes a well-known suction device such as a vacuum cleaner, and may also have such a nozzle shape that a swirling current of air is generated at the head of the suction nozzle. The removal method by sucking may also be conducted after the adhesive force has been previously lowered by heating or the like, or may also be conducted simultaneously while forming the wound body of the surface protection sheet for dicing by heating or the like.

The method of removing the surface protection sheet for dicing by sucking may also be conducted by preheating the adherend and the surface protection sheet for dicing, which has been formed into the wound body, with a heating medium such as the hot plate. In this case, the preheating temperature by the heating medium can be set at 50° C. to 70° C., for instance.

The method of concomitantly using the above described blowing method and the method by sucking is further desirable from the viewpoint of decreasing the possibility of the blown surface protection sheet for dicing to spread, because of simultaneously sucking the blown surface protection sheet for dicing.

When concomitantly using the methods, it is necessary to position a nozzle for blowing and a nozzle for sucking closely to the surface protection sheet for dicing or provide a spouting port for spouting a gas and a sucking port adjacently in one nozzle. In addition, in order to surely suck the blown surface protection sheet for dicing in particular, it is necessary to enlarge the nozzle for sucking or the sucking port so as to cover the range in which the spouted gas spreads.

FIG. 4 and FIG. 5 are sectional views illustrating one example of the surface protection sheet for dicing to be used in the present invention. The surface protection sheet for dicing illustrated in FIG. 4 and FIG. 5 includes a shrinkable film layer 10 having uniaxially-shrinking properties, a constraining layer 11 which constrains the shrinkage of the shrinkable film layer 10, a tackiness agent layer 14, and an intermediate layer 15, as needed.

The shrinkable film layer 10 may be a film layer having shrinking properties in at least one axial direction, and may also be constituted by any of a heat-shrinkable film, a film showing shrinking properties by light, a film shrunk by an electrical stimulus and the like. Among the films, the film layer is preferably constituted by the heat-shrinkable film, from the viewpoint of operation efficiency and the like.

The constraining layer 11 is constituted by an elastic layer 12 in the shrinkable film layer 10 side and a rigid film layer 13 in the opposite side of the shrinkable film layer 10. The surface protection sheet for dicing illustrated in FIG. 4 has the tackiness agent layer 14 laminated on the rigid film layer 13 side.

Though being unshown in the figure, a release liner may also be laminated on the surface of the tackiness agent layer 14 of the surface protection sheet for dicing, similarly to a general adhesive sheet having the release liner provided on the surface of the tackiness agent layer.

The surface protection sheet for dicing in FIG. 5 is a laminated body having the shrinkable film layer 10, the elastic layer 12 and the rigid film layer 13 working as the constraining layer 11, the intermediate layer 15 and the tackiness agent layer 14 laminated in this order, is spontaneously wound toward one direction from one end or toward the center from opposing two ends by the impartment of the stimulus which becomes the cause of the shrinkage, such as heating, and can form one or two pieces of cylindrical wound bodies.

The intermediate layer 15 is positioned between the above described rigid film layer 13 and the tackiness agent layer 14, and has the function of alleviating a tensile stress of a composite substrate formed of shrinkable film layer/elastic layer/rigid film layer, and thereby reducing the warp of the wafer, which occurs when the wafer is extremely thinly ground. The feature of the intermediate layer 15 is to show low elasticity compared to the above described rigid film layer.

The surface protection sheet for dicing preferably has a configuration in which the shrinkable film layer having shrinking properties in at least one axial direction and an active energy beam curing type tackiness agent layer that is cured by being irradiated with an active energy beam to have such a tensile modulus of elasticity that a product of the tensile modulus of elasticity and the thickness at 80° C. becomes 5×10³ N/m or more and less than 1×10⁵ N/m are laminated, and spontaneously winds toward one direction from one end or toward the center from opposing two ends by being heated to be capable of forming one or two pieces of cylindrical wound bodies. The surface protection sheet for dicing may also have another layer between the above described shrinkable film layer and the active energy beam curing type tackiness agent layer in the range of not impairing the spontaneous winding properties, but does not preferably have such a layer that the product of tensile modulus of elasticity and the thickness at 80° C. becomes 4×10⁵ N/m or more (1×10⁵ N/m or more, in particular).

### [Shrinkable Film Layer]

The shrinkable film layer 10 may be a film layer having shrinking properties in at least one axial direction by heating, but may have shrinking properties in only one axial direction or may also have main shrinking properties in a certain direction (one axial direction) and secondary shrinking properties in a direction different from the above direction (direction perpendicular to the above direction, for instance). The shrinkable film layer 10 may also be a monolayer, or may also be a multilayer having two or more layers.

A shrinkage rate of the main shrinking direction of the shrinkable film layer 10 is 3 to 90% at a predetermined temperature in the range of 40 to 180° C., preferably is 5 to 90%, further preferably is 10 to 90%, and particularly preferably is 20 to 90%. The shrinkage rate in a direction other than the main shrinking direction of the shrinkable film layer constituting the shrinkable film layer is preferably 10% or less, further preferably is 5% or less, and particularly preferably is 3% or less. The heat shrinkability of the shrinkable film layer can be imparted by subjecting the film, for instance, extruded by an extruder to stretching treatment.

For information, in the present specification, a shrinkage rate (%) means a value calculated by the expression of [(dimension before shrinkage−dimension after shrinkage)/(dimension before shrinkage)]×100, and represents a shrinkage rate in the main shrinking axis direction, unless otherwise specifically indicated.

The above described shrinkable film layer 10 includes, for instance, a uniaxially stretched film formed from one or more resins selected from: a polyester such as polyethylene terephthalate; a polyolefin such as polyethylene and polypropylene; polynorbornene; a polyimide; a polyamide; polyurethane; polystyrene; polyvinylidene chloride; polyvinyl chloride; and the like. Among the resins, the uniaxially stretched films formed from the polyester-based resin, the polyolefin-based resin (including cyclic polyolefin-based resin) such as polyethylene, polypropylene and polynorbornene and/or the polyurethane-based resin are preferable because the coating workability and the like of the tackiness agent are excellent. A usable commercial product of such a shrinkable film layer includes “Space clean” made by Toyobo Co., Ltd., “FANCYWRAP” made by Gunze Plastics & Engineering Corporation, “Torayfan” made by Toray Industries, Inc., “Lumirror” made by Toray Industries, Inc., “ARTON” made by JSR Corporation, “ZEONOR” made by ZEON CORPORATION and “SUNTEC” made by Asahi Kasei Corporation.

Here, when using the surface protection sheet for dicing and irradiating the active energy beam curing type tackiness agent layer with an active energy beam through the shrinkable film layer 10 to cure the tackiness agent layer, the shrinkable film layer 10 needs to be constituted by a material through which a predetermined amount or more of the active energy beam can pass (for instance, resin having transparency and the like).

The thickness of the shrinkable film layer 10 is generally 5 to 300 μm, and preferably is 10 to 100 μm. When the thickness of the shrinkable film layer 10 is too large, the rigidity becomes high, the shrinkable film layer 10 does not spontaneously wind, and separation occurs between the shrinkable film layer and the active energy beam curing type tackiness agent layer after having been irradiated with the active energy beam, which tends to lead to the fracture of the laminated body. In addition, a film having a large rigidity makes a stress remain therein when the tape has been affixed, has a large elastic deformation force and forms a large warp when the wafer has been thinned, and the adherend tends to be easily damaged by transportation and the like.

In order to enhance the firm adhesion, retentivity and the like to the adjacent layer, the surface of the shrinkable film layer 10 may also be subjected to conventional surface treatment, for instance; chemical or physical treatment such as chromate treatment, ozone exposure, flame exposure, high-pressure electrical shock exposure and ionized radioactive ray treatment; coating treatment by an undercoating agent (tack substance and the like, for instance); and the like.

### [Constraining Layer]

The constraining layer 11 constrains the shrinkage of a shrinkable film layer 10, generates a counteracting force, thereby generates a couple as the whole laminated body, and converts the couple into a driving force which causes winding. In addition, it is considered that this constraining layer 11 reduces a secondary shrinkage in a direction different from the main shrinking direction of the shrinkable film layer 10, and also has the function of converging the shrinking direction of the shrinkable film layer 10 to one direction, which is considered to have uniaxially-shrinking properties but does not necessarily have uniform uniaxially-shrinking properties.

Because of this, it is considered that when a heat for promoting the shrinkage of the shrinkable film layer 10 is applied to a single laminated sheet, a repulsive force with respect to the shrinking force of the shrinkable film layer 10 in the constraining layer 11 works as a driving force, lifts up the outer edge (one end or opposing two ends) of the laminated sheet, and spontaneously winds the laminated sheet toward one direction or a center direction (normally, main shrinking axis direction of shrinkable film layer) from the ends so that the shrinkable film layer 10 side comes inside to form a cylindrical wound body.

In addition, this constraining layer 11 can prevent a shearing force generated by the shrinkage and deformation of the shrinkable film layer 10 from being transmitted to a tackiness agent layer 14 and an adherend, accordingly can prevent damage to the tackiness agent layer (cured tackiness agent layer, for instance) having the tack force lowered and damage to the adherend from occurring when the surface protection sheet for dicing is peeled, and can prevent the contamination of the adherend by the above described broken tackiness agent layer and the like.

The constraining layer 11 has adhesiveness (including tackiness) with respect to an elastic layer 12 and the shrinkable film layer 10 so as to develop the function of constraining the shrinkage of the shrinkable film layer 10. In addition, the constraining layer 11 preferably has some toughness or rigidity so as to make the cylindrical wound body smoothly formed. The constraining layer 11 may be constituted by a monolayer, or may also be constituted by a multilayer having a plurality of layers which share functions. The constraining layer 11 is preferably constituted by the elastic layer 12 and a rigid film layer 13.

### [Elastic Layer]

The elastic layer 12 is preferably easily deformed at a temperature at which a shrinkable film layer 10 is shrunk, in other words, is preferably in a rubber state. However, a flexible material does not generate a sufficient counteracting force, and the shrinkable film layer results in shrinking solely finally and cannot cause deformation (spontaneous winding). Accordingly, the elastic layer 12 preferably has the flexibility reduced by three-dimensional crosslinking or the like. In addition, the elastic layer 12 has the action of converting nonuniform shrinking forces of the shrinkable film layer 10 into the force of a uniform shrinking direction by resisting a component having a weaker force among the nonuniform shrinking forces also by the thickness, and preventing the shrinkage and deformation due to the component having the weaker force. It is considered that the warp caused by grinding for the wafer is generated by the elastic deformation of the shrinkable film layer due to the remaining stress which has remained when the surface protection sheet for dicing has been affixed to the wafer, but the elastic layer also has the function of alleviating this remaining stress to decrease the warp.

Accordingly, it is desirable that the elastic layer 12 has tackiness and is formed by a resin having a glass transition temperature, for instance, of 50° C. or lower, preferably of room temperature (25° C.) or lower and more preferably of 0° C. or lower. The tack force of the surface in the shrinkable film layer 10 side of the elastic layer 12 is preferably in the range of 0.5 N/10 mm or more by a value due to the 180° peel peeling test (according to JIS 20237, at a pulling rate of 300 mm/minute, at 50° C.). When this tack force is too low, peeling tends to easily occur between the shrinkable film layer 10 and the elastic layer 12.

In addition, the shear modulus of elasticity G of the elastic layer 12 is preferably 1×10⁴ Pa to 5×10⁶ Pa (particularly, 0.05×10⁶ Pa to 3×10⁶ Pa) at a temperature between room temperature (25° C.) and a temperature when the surface protection sheet is peeled (80° C., for instance). This is because when the shear modulus of elasticity is too small, the action of converting the shrinkage stress of the shrinkable film layer to the stress necessary for winding becomes poor, and on the contrary, when the shear modulus of elasticity is too large, the winding properties become poor because of enhancing rigidity, and besides, the elastic layer having high elasticity generally has poor tackiness, tends to make the production of a laminated body difficult and becomes poor in the action of alleviating the remaining stress. The thickness of the elastic layer 12 is preferably approximately 15 to 150 μm. When the above described thickness is too thin, it is difficult to obtain the constraining properties with respect to the shrinkage of the shrinkable film layer 10, and an effect of alleviating the stress also becomes small. On the contrary, when the thickness is too thick, spontaneously winding properties decrease, and handleability and economical efficiency are inferior, which are not preferable. Accordingly, the product of the shear modulus of elasticity G (by value at 80° C., for instance) and the thickness of the elastic layer 12 (shear modulus of elasticity G×thickness) is preferably 1 to 1,000 N/m (more preferably is 1 to 150 N/m, and further preferably is 1.2 to 100 N/m).

In addition, when the tackiness agent layer 14 is an active energy beam curing type tackiness agent layer, it is preferable that the elastic layer 12 is formed from a material through which an active energy beam easily passes, can appropriately select the thickness from the viewpoint of manufacture, workability and the like, is easily formed into a film shape and has excellent formability.

A usable elastic layer 12 includes, for instance, a foam material (foamed thin sheet) such as urethane foam and acrylic foam having the surface (which is at least on shrinkable film layer 10 side) subjected to a tack treatment, and a resin film (including sheet) such as a nonfoaming resin film which employs a rubber, a thermoplastic elastomer and the like as the material. The tackiness agent to be used for the tack treatment is not limited in particular, and the known tackiness agents can be used solely or in combination with other one or more types, which include, for instance, an acrylic tackiness agent, a rubber-based tackiness agent, a vinylalkyl ether-based tackiness agent, a silicone-based tackiness agent, a polyester-based tackiness agent, a polyamide-based tackiness agent, a urethane-based tackiness agent and a styrene-diene block copolymer-based tackiness agent. In particular, the acrylic tackiness agent is preferably used from the viewpoint of the adjustment of the tack force and the like. In addition, the resin of the tackiness agent to be used for the tack treatment and the resin of the foamed thin sheet or the nonfoaming resin film preferably belong to the same type of resin so as to obtain high compatibility. For instance, when the acrylic tackiness agent is used for the tack treatment, the acrylic foam and the like are preferable as the foam material.

In addition, the elastic layer 12 may also be formed from a resin composition having adhesiveness by itself, for instance, like a crosslinking type ester-based tackiness agent and a crosslinking type acrylic tackiness agent. Such layers (tackiness agent layers) formed from the crosslinking type ester-based tackiness agent, the crosslinking type acrylic tackiness agent and the like can be manufactured with a comparatively simple method without separately being subjected to the tack treatment, have excellent productivity and economical efficiency, and accordingly are preferably used.

The above described crosslinking type ester-based tackiness agent has a composition formed by adding a crosslinking agent to the ester-based tackiness agent which employs an ester-based polymer as a base polymer. The ester-based polymer includes, for instance, a polyester formed of a condensed polymer of a diol and a dicarboxylic acid.

An example of the diol includes, for instance, a (poly)carbonate diol. The (poly)carbonate diol includes, for instance, (poly)hexamethylene carbonate diol, (poly)3-methyl(pentamethylene)carbonate diol, (poly)trimethylene carbonate diol and a copolymer thereof. The diol component or the (poly)carbonate diol can be used singly or in combinations of one or more. In addition, when the (poly)carbonate diol is polycarbonatediol, the polymerization degree is not limited in particular.

The commercial product of the (poly)carbonate diol includes, for instance, a trade name “PLACCEL CD208PL”, a trade name “PLACCEL CD210PL”, a trade name “PLACCELCD220PL”, a trade name “PLACCEL CD208”, a trade name “PLACCELCD210”, a trade name “PLACCEL CD220”, a trade name “PLACCEL CD208HL”, a trade name “PLACCELCD210HL”, and a trade name “PLACCELCD220HL” [all the products made by DAICEL CHEMICAL INDUSTRIES, LTD.].

The diol component may also be used concomitantly with a component such as ethylene glycol, propylene glycol, butanediol, hexanediol, octanediol, decanediol and octadecanediol, as needed, in addition to the (poly) carbonate diol.

In addition, a preferably usable dicarboxylic acid component includes: a dicarboxylic acid that contains an aliphatic or alicyclic hydrocarbon group having 2 to 20 carbon atoms as a molecular skeleton; and a dicarboxylic acid component which contains a reactive derivative thereof as an indispensable component. In the above described dicarboxylic acid which contains the aliphatic or alicyclic hydrocarbon group having 2 to 20 carbon atoms as the molecular skeleton or the reactive derivative thereof, the hydrocarbon group may be straight-chained or may also be branch-chained. Representative examples of such a dicarboxylic acid or a reactive derivative thereof include succinic acid, methylsuccinic acid, adipic acid, pimelic acid, azelaic acid, sebacic acid, 1,12-dodecanedioic acid, 1,14-tetradecanedioic acid, tetrahydrophthalic acid, endomethylene tetrahydrophthalic acid, and an acid anhydride thereof and a lower alkyl ester thereof. The dicarboxylic acid component can be used singly or in combinations of one or more.

A preferably usable combination of the diol and the dicarboxylic acid includes polycarbonatediol and sebacic acid, adipic acid, pimelic acid, suberic acid, azelaic acid, phthalic acid or maleic acid.

The above described crosslinking type acrylic tackiness agent has a composition formed by adding a crosslinking agent to the acrylic tackiness agent which employs an acrylic polymer as a base polymer. The acrylic polymer includes, for instance, a single compound or a copolymer of an alkyl(meth)acrylate such as a C1-C20 alkyl (meth)acrylate such as methyl (meth)acrylate, ethyl (meth)acrylate, butyl (meth)acrylate, 2-ethylhexyl(meth)acrylate and octyl (meth)acrylate; and a copolymer of the above described alkyl (meth)acrylate with another copolymerizable monomer [for instance, a monomer containing a carboxyl group or an acid anhydride group such as acrylic acid, methacrylic acid, itaconic acid, fumaric acid and maleic acid anhydride; a monomer containing a hydroxyl group such as 2-hydroxyethyl (meth)acrylate; a monomer containing an amino group such as morpholyl (meth)acrylate; a monomer containing an amide group such as (meth)acrylamide; a monomer containing a cyano group such as (meth)acrylonitrile; a (meth)acrylate having an alicyclic hydrocarbon group such as isobornyl (meth)acrylate; and the like].

A particularly preferable acrylic polymer is a copolymer of one or more C1-C12 alkyl (meth)acrylates such as ethyl acrylate, butyl acrylate and 2-ethylhexyl acrylate with at least one copolymerizable monomer selected from a monomer containing a hydroxyl group such as 2-hydroxyethyl acrylate and a monomer containing a carboxyl group or an acid anhydride group such as acrylic acid, or a copolymer of one or more C1-C12 alkyl (meth)acrylates, a (meth)acrylate having an alicyclic hydrocarbon group, and at least one copolymerizable monomer selected from a monomer containing a hydroxyl group and a monomer containing a carboxyl group or an acid anhydride group.

The acrylic polymer is prepared as a high-viscosity liquid prepolymer by polymerizing, for instance, the above described illustrated monomer component (and photopolymerization initiator) with light (ultraviolet rays or the like) without using a solvent. Subsequently, a crosslinking agent is added to this prepolymer, and thereby the crosslinking type acrylic tackiness agent composition can be obtained. Here, the crosslinking agent may also be added to the prepolymer when the prepolymer is produced. In addition, the crosslinking type acrylic tackiness agent composition can be obtained also by adding the crosslinking agent and a solvent (which is not necessarily needed when the acrylic polymer solution is used) to the acrylic polymer obtained by polymerizing the above described illustrated monomer component or the solution thereof.

A usable crosslinking agent is not limited in particular, and includes, for instance, an isocyanate-based crosslinking agent, a melamine-based crosslinking agent, an epoxy-based crosslinking agent, an acrylate-based crosslinking agent (polyfunctional acrylate) and a (meth)acrylate having an isocyanate group. Examples of the acrylate-based crosslinking agent include, for instance, hexanediol diacrylate, 1,4-butanediol diacrylate, trimethylolpropane triacrylate, pentaerythritol tetraacrylate and dipentaerythritol hexaacrylate. Examples of the (meth)acrylate having the isocyanate group include, for instance, 2-isocyanato ethyl acrylate and 2-isocyanatoethyl methacrylate. Among the crosslinking agents, preferable crosslinking agents are an ultraviolet (UV) reactive crosslinking agent such as the acrylate-based crosslinking agent (polyfunctional acrylate) and the (meth)acrylate having the isocyanate group. The amount of the crosslinking agent to be added is usually approximately 0.01 to 150 parts by weight with respect to 100 parts by weight of the above described base polymer, preferably is approximately 0.05 to 50 parts by weight, and particularly preferably is approximately 0.05 to 30 parts by weight.

The crosslinking type acrylic tackiness agent may also contain an appropriate additive such as a crosslinking promoter, a tackifier (for instance, rosin derivative resin, polyterpene resin, petroleum resin, oil-soluble phenol resin and the like), a thickener, a plasticizer, a filler, an anti-aging agent, an antioxidant and the like, in addition to the base polymer and the crosslinking agent.

The crosslinking type acrylic tackiness agent layer working as the elastic layer 12 can be simply obtained so as to match the purpose, by forming the crosslinking type acrylic tackiness agent composition which has been prepared by adding the crosslinking agent to the above described polymer into a film shape having a desired thickness and area with a known method such as a casting method, and irradiating the tackiness agent composition with light again to progress a crosslinking reaction (and polymerization of unreacted monomer), for instance. Thus obtained elastic layer (crosslinking type acrylic tackiness agent layer) has self-tackiness, accordingly can be affixed between the shrinkable film layer 10 and the rigid film layer 13 in the state and can be used. A usable crosslinking type acrylic tackiness agent layer includes a commercial double-sided adhesive tape such as a trade name “HJ-9150W” made by NITTO DENKO CORPORATION. In addition, it is also acceptable to progress the crosslinking reaction by irradiating the film-shaped tackiness agent with light again after having affixed the tackiness agent between the shrinkable film layer 10 and the rigid film layer 13.

The crosslinking type acrylic tackiness agent layer working as the elastic layer 12 can also be obtained by coating the crosslinking type acrylic tackiness agent composition which has been prepared by dissolving the above described acrylic polymer and the crosslinking agent in a solvent on the surface of the rigid film layer 13, affixing the shrinkable film layer 10 thereon, and then irradiating the film layer with light. However, when the tackiness agent layer 14 is an active energy beam curing type tackiness agent layer, the above described crosslinking type acrylic tackiness agent may also be cured (crosslinked) by irradiation with the active energy beam (light irradiation), which is conducted in order to cure the tackiness agent layer 14 when the surface protection sheet for dicing is peeled.

Beads such as glass beads and resin beads may also be added to the component of the elastic layer 12 in the present invention. The addition of the glass beads or the resin beads into the elastic layer 12 is advantageous in such a point that tack characteristics and shear modulus of elasticity are easily controlled. The average particle diameter of the beads is, for instance, 1 to 100 μm, and preferably is approximately 1 to 20 μm. The amount of the beads to be added is, for instance, 0.1 to 10 parts by weight with respect to 100 parts by weight of the whole elastic layer 12, and preferably is 1 to 4 parts by weight. When the above described amount of the beads to be added is too large, the tack characteristics occasionally decrease. When the above described amount is too small, the above described effect tends to become insufficient.

### [Rigid Film Layer]

The rigid film layer 13 has the function of imparting rigidity or toughness to a constraining layer 11, thereby generating a counteracting force with respect to the shrinking force of a shrinkable film layer 10, and consequently generating a couple necessary for winding. By being provided with the rigid film layer 13, the surface protection sheet for dicing can smoothly spontaneously wind without stopping the action on the way or misaligning the direction to form a cylindrical wound body having a neat shape, when the stimulus which becomes the cause of the shrinkage, such as heating, has been imparted to the shrinkable film layer 10.

The rigid film constituting the rigid film layer 13 includes a film, for instance, formed from one or more resins selected from: a polyester such as polyethylene terephthalate, polybutylene terephthalate and polyethylene naphthalate; a polyolefin such as polyethylene and polypropylene; a polyimide; a polyamide; a polyurethane; a styrene-based resin such as polystyrene; polyvinylidene chloride; and polyvinyl chloride. Among the rigid films, the polyester-based resin film, the polypropylene film, the polyamide film and the like are preferable in the point of being excellent in the coating workability and the like of the tackiness agent. The rigid film layer 13 may be a monolayer or may also be a multilayer having two or more layers laminated. The rigid film constituting the rigid film layer 13 has unshrinking properties, and the shrinkage rate is, for instance, 5% or less, preferably is 3% or less, and further preferably is 1% or less.

The product of the Young's modulus and the thickness (Young's modulus×thickness) of the rigid film layer 13 is preferably 3.0×10⁵ N/m or less (1.0×10² to 3.0×10⁵ N/m, for instance) at a temperature in a peeling operation (80° C., for instance), and further preferably is 2.8×10⁵ N/m or less (1.0×10³ to 2.8×10⁵ N/m, for instance). When the product of the Young's modulus and the thickness of the rigid film layer 13 is too small, the action of converting the shrinkage stress of the shrinkable film layer 10 to a winding stress is poor, and a direction-converging action also tends to decrease. On the contrary, when the product is too large, the winding action tends to be suppressed by the rigidity. The Young's modulus of the rigid film layer 13 is preferably 3×10⁶ to 2×10¹⁰ N/m² at a temperature in a peeling operation (80° C., for instance), and further preferably is 1×10⁸ to 1×10¹⁰ N/m². When the Young's modulus is too small, it becomes difficult to obtain a cylindrical wound body which has been wound to have a neat shape. On the contrary, when the Young's modulus is too large, the spontaneous winding action becomes difficult to occur. The thickness of the rigid film layer 13 is, for instance, 20 to 150 μm, preferably is 25 to 95 μm, further preferably is 30 to 90 μm, and particularly preferably is approximately 30 to 80 μm. When the above described thickness is too thin, it becomes difficult to obtain a cylindrical wound body which has been wound to have a uniform shape. When the thickness is too thick, the spontaneous winding properties decrease, and the handleability and the economical efficiency are inferior, which are not preferable.

In addition, when the tackiness agent layer 14 is an active energy beam curing type tackiness agent layer, it is preferable that the rigid film layer 13 is formed from a material through which an active energy beam easily passes, can appropriately select the thickness from the viewpoint of manufacture, workability and the like, is easily formed into a film shape and has excellent formability.

In the above described example, the constraining layer 11 is constituted by the elastic layer 12 and the rigid film layer 13, but does not necessarily need to be constituted in such a way. The rigid film layer 13 can be also omitted by imparting adequate rigidity to the elastic layer 12, for instance.

### [Tackiness Agent Layer]

The tackiness agent layer 14 can also employ a tackiness agent layer originally having small tack force, but is preferably a repeelable tackiness agent layer which has the tackiness bondable to the wafer 2 and can lower or extinguish the tackiness by a certain method (low-tack treatment) after having finished a predetermined role. In addition, it is necessary to have a stronger adhesive force with respect to a wafer than that of the tackiness agent layer of a dicing tape.

Such a repeelable tackiness agent layer can be constituted similarly to the tackiness agent layer of a known repeelable adhesive sheet. From the viewpoint of spontaneous winding properties, the tack force (180° C. peel peeling test with respect to the silicon mirror wafer at a pulling rate of 300 mm/min) of the tackiness agent layer or the tackiness agent layer after low-tack treatment, for instance, at normal temperature (25° C.) is desirably 6.5 N/10 mm or less (6.0 N/10 mm or less in particular).

A preferably usable tackiness agent layer 14 includes an active energy beam curing type tackiness agent layer. The active energy beam curing type tackiness agent layer can be constituted by the material which has tackiness and adhesiveness in the early stage, and forms a three-dimensional network structure by irradiation with an active energy beam such as infrared rays, visible light, ultraviolet rays, X-rays and an electron beam to become highly elasticated. An active energy beam curing type tackiness agent and the like can be used for such a material. The active energy beam curing type tackiness agent includes a compound which has an active energy beam reactive functional group for imparting active energy beam curability chemically modified, or an active energy beam curable compound (or an active energy beam curable resin). Accordingly, a preferably usable active energy beam curing type tackiness agent is constituted by a base agent which is chemically modified by the active energy beam reactive functional group, or a composition which is a base agent blended with an active energy beam curable compound (or an active energy beam curable resin).

The active energy beam curing type tackiness agent layer has sufficient tack force to be bonded to the wafer 2 and prevent “crack” or “chipping” from occurring in the wafer 2, before being irradiated with the active energy beam; forms the three-dimensional network structure by being irradiated with the active energy beam such as infrared rays, visible light, ultraviolet rays, X-rays and the electron beam to be cured and lowers the tack force to the wafer 2, after having been processed; and can also show the action of repulsing the shrinkage as a constraining layer when the above described shrinkable film layer shrinks due to heat, accordingly convert the repulsive force with respect to the shrinkage into a driving force, and lifts up an outer edge (end) of the surface protection sheet for dicing. Then, the surface protection sheet spontaneously winds toward one direction from an end or toward the center (the center of two ends) from opposing two ends so that the shrinkable film layer side comes inside, and can form one or two cylindrical wound bodies.

A usable base agent includes, for instance, conventionally known tack substances such as a pressure-sensitive adhesive agent (tackiness agent). Examples of the tackiness agent include: a rubber-based tackiness agent which uses a rubber-based polymer such as natural rubber, polyisobutylene rubber, styrene-butadiene rubber, styrene-isoprene-styrene block copolymer rubber, reclaimed rubber, butylene rubber and NBR, as a base polymer; a silicone-based tackiness agent; and an acrylic tackiness agent. Among the tackiness agents, the acrylic tackiness agent is preferable. The base agent may be constituted by one type of component or two or more types of components.

The examples of the acrylic tackiness agent include acrylic tackiness agents that use acrylic polymers as a base polymer, which include, for instance: a single compound or a copolymer of an alkyl (meth)acrylate such as a C1-C20 alkyl (meth)acrylate such as methyl (meth)acrylate, ethyl (meth)acrylate, butyl (meth)acrylate, 2-ethylhexyl (meth)acrylate and octyl (meth)acrylate; and a copolymer of the above described alkyl (meth)acrylate with another copolymerizable monomer [for instance, a monomer containing a carboxyl group or an acid anhydride group, such as acrylic acid, methacrylic acid, itaconic acid, fumaric acid and maleic acid anhydride; a monomer containing a hydroxyl group, such as 2-hydroxyethyl (meth)acrylate; a monomer containing an amino group, such as morpholyl (meth)acrylate; a monomer containing an amide group, such as (meth)acrylamide; and the like]. These tackiness agents can be used singly or in combinations of one or more.

The active energy beam reactive functional group which is used for chemically modifying the active energy beam curing type tackiness agent so as to be cured by the active energy beam, and the active energy beam curable compound are not limited in particular, as long as the functional group and the curable compound can be cured by the active energy beam such as infrared rays, visible light, ultraviolet rays, X-rays and an electron beam, but preferably can efficiently three-dimensionally reticulate (net) the active energy beam curing type tackiness agent after having been irradiated with the active energy beam. These functional groups and curable compounds can be used singly or in combinations of one or more. The active energy beam reactive functional group used for the chemical modification includes, for instance, a functional group which has a carbon-carbon multiple bond, such as an acryloyl group, a methacryloyl group, a vinyl group, an allyl group and an acetylene group. These functional groups cleave the carbon-carbon multiple bond by irradiation with the active energy beam to produce a radical, and can form three-dimensional network structure while this radical works as a crosslinking point. Among the functional groups, the (meth)acryloyl group can show relatively high reactivity with respect to the active energy beam, and can be used in combination with an acrylic tackiness agent that has been selected from abundant types thereof, which are preferable in the viewpoint of reactivity and workability.

Representative examples of the base agent which has been chemically modified with the active energy beam reactive functional group includes a polymer obtained by making an acrylic polymer containing a reactive functional group which has been prepared by copolymerizing a monomer that includes a reactive functional group such as a hydroxyl group and a carboxyl group [for instance, 2-hydroxyethyl (meth)acrylate, a (meth)acrylate and the like] with an alkyl (meth)acrylate react with a compound having a group which reacts with the above described reactive functional group (isocyanate group, epoxy group and the like) in the molecule, and having an active energy beam reactive functional group (acryloyl group, methacryloyl group and the like) in the molecule[for instance, (meth)acryloyl oxyethylene isocyanate].

The ratio of the monomer containing the reactive functional group in the acrylic polymer containing the above described reactive functional group is, for instance, 5 to 40 wt % with respect to all the monomers, and preferably is 10 to 30 wt %. The amount of the compound to be used which has the group that reacts with the above described reactive functional group when being reacted with the above described acrylic polymer containing the reactive functional group, and has the active energy beam reactive functional group in the molecule is, for instance, 50 to 100 mol % with respect to the reactive functional group (hydroxyl group, carboxyl group and the like) in the acrylic polymer containing the reactive functional group, and preferably is 60 to 95 mol %.

The active energy beam curable compound includes a compound having two or more carbon-carbon double bonds, for instance, such as a compound containing poly(meth)acryloyl group, such as trimethylolpropane triacrylate, tetramethylolmethane tetraacrylate, pentaerythritol triacrylate, pentaerythritol tetraacrylate, dipentaerythritol monohydroxypentaacrylate, dipentaerythritol hexaacrylate, 1,4-butanediol diacrylate, 1,6-hexanediol diacrylate and polyethylene glycol diacrylate. These compounds may be used singly or in combinations of one or more. Among the compounds, the compound containing a poly(meth)acryloyl group is preferable, and is illustrated, for instance, in Japanese Patent Laid-Open No. 2003-292916. Hereinafter, the compound containing the poly(meth)acryloyl group is occasionally referred to as “acrylate-based crosslinking agent.”

A usable active energy beam curable compound also can include a mixture of an organic salt such as an onium salt and a compound which has a plurality of heterocycles in the molecule. The above described mixture produces an ion by the cleavage in the organic salt, which has been caused by being irradiated with an active energy beam, the ion works as a initiation seed to trigger a ring-opening reaction of the heterocycle, and the mixture can form a three-dimensional network structure. The above described organic salt includes an iodonium salt, a phosphonium salt, an antimonium salt, a sulfonium salt and a borate salt; and the heterocycle in the above described compound having the plurality of the heterocycles in the molecule includes oxirane, oxetane, oxorane, thiirane and aziridine. Specifically, a compound can be used which is described in Photo-Curing Technology (2000) edited by Technical Information Institute Co., Ltd.

The active energy beam curable resin includes, for instance; an ester (meth)acrylate, a urethane (meth)acrylate, an epoxy (meth)acrylate, a melamine (meth)acrylate, an acrylic resin (meth)acrylate, which have a (meth)acryloyl group in the molecule end; a thiol-ene addition type resin and a photo-cationic polymerization type resin which have an allyl group in the molecule end; and a polymer or an oligomer containing a photosensitive reaction group, such as a polymer containing a cinnamoyl group such as polyvinyl cinnamate, a diazotized amino novolak resin and an acrylamide type polymer. Furthermore, a polymer which reacts with a hyperactive energy beam includes epoxidized polybutadiene, an unsaturated polyester, polyglycidyl methacrylate, polyacrylamide and polyvinyl siloxane. Here, when the active energy beam curable resin is used, the above described base agent is not necessarily needed.

Among the resins, it is preferable to use an oligomer which has the acryloyl group or the methacryloyl group in the molecule, such as the ester (meth)acrylate, the urethane (meth)acrylate, the epoxy (meth)acrylate, the melamine (meth)acrylate and the acrylic resin (meth)acrylate, in the point of being capable of showing relatively high reactivity with respect to the active energy beam.

A molecular weight of the active energy beam curable resin is, for instance, approximately less than 5,000, and preferably is approximately 100 to 3,000. When the molecular weight of the active energy beam curable resin exceeds 5,000, the compatibility, for instance, with the acrylic polymer (base agent) tends to decrease.

A particularly preferable active energy beam curing type tackiness agent is a combination of the above described acrylic polymer or the acrylic polymer which has been chemically modified with the active energy beam reactive functional group (acrylic polymer in which active energy beam reactive functional group has been introduced into the side chain) with the above described active energy beam curable compound (compound having two or more carbon-carbon double bonds or the like), from the viewpoints of many choices and easy adjustment of the modulus of elasticity before and after the irradiation with the active energy beam. The above described combination contains an acrylate group showing the relatively high reactivity with respect to the active energy beam, can also select the compound from various types of acrylic tackiness agents, and accordingly is preferable from the viewpoint of reactivity and workability. The specific example of such a combination can be selected from various acrylic tackiness agents, but can include a combination of the acrylic polymer in which a (meth)acryloyl group has been introduced in the side chain, with a compound having two or more functional groups (particularly acrylate group) having carbon-carbon double bonds, such as an oligomer which shows relatively high reactivity and has an acryloyl group or a methacryloyl group in the molecule. A combination disclosed in Japanese Patent Laid-Open No. 2003-292916 can be used as such a combination.

A preferable embodiment to be used of the active energy beam curing type tackiness agent includes the acrylic tackiness agent containing the side chain (meth)acryloyl group, the oligomer having the acryloyl group or the methacryloyl group in the molecule, an acrylate-based crosslinking agent (compound containing poly(meth)acryloyl group; polyfunctional acrylate), and a UV curing type tackiness agent containing an ultraviolet photopolymerization initiator, in particular.

A usable method of preparing an acrylic polymer in which an acrylate group has been introduced in the above described side chain includes, for instance, a method of combining an acrylic polymer which contains a hydroxyl group in the side chain, with an isocyanate compound such as acryloyloxyethyl isocyanate and methacryloyloxyethyl isocyanate, through a urethane bond.

The amount of the active energy beam curable compound to be blended is, for instance, approximately 0.5 to 200 parts by weight with respect to 100 parts by weight of a base agent (for instance, the above described acrylic polymer or the acrylic polymer which has been chemically modified with the active energy beam reactive functional group), preferably is 5 to 180 parts by weight, and further preferably is approximately 20 to 130 parts by weight.

The active energy beam curing type tackiness agent may be blended with an active energy beam polymerization initiator for curing the compound which imparts the active energy beam curability, for the purpose of the enhancement of the velocity and the like of the reaction which forms the three-dimensional network structure.

The active energy beam polymerization initiator can appropriately select a known or conventional polymerization initiator, according to the type of the active energy beam to be used (for instance, infrared rays, visible light, ultraviolet rays, X-rays, electron beam and the like). A compound which can initiate photopolymerization by ultraviolet rays is preferable from the aspect of working efficiency. A representative active energy beam polymerization initiator includes: a ketone-based initiator such as benzophenone, acetophenone, quinone, naphthoquinone, anthraquinone and fluorenone; an azo-based initiator such as azobisisobutyronitrile; a peroxide-based initiator such as benzoyl peroxide and perbenzoic acid. However, the initiator is not limited to those. There are commercialized products, for instance, such as “IRGACURE 184” and “IRGACURE 651” by trade name made by Ciba-Geigy Corporation.

The active energy beam polymerization initiator can be used singly or in mixtures of one or more. The amount of the active energy beam polymerization initiator to be blended is normally approximately 0.01 to 10 parts by weight with respect to 100 parts by weight of the above described base agent, and preferably is approximately 1 to 8 parts by weight. For information, the above described active energy beam polymerization initiator may be concomitantly used with an active energy beam polymerization accelerator, as needed.

In addition to the above described components, the active energy beam curing type tackiness agent is blended with an appropriate additive such as a crosslinking agent, a curing (crosslinking) accelerator, a tackifier, a vulcanizing agent and a thickener, in order to obtain appropriate tackiness before and after an active energy beam curing operation, and an appropriate additive such as an antiaging agent and an antioxidant, in order to enhance durability, as needed.

A preferable active energy beam curing type tackiness agent to be used includes, for instance, a composition in which the active energy beam curable compound is blended in a base agent (tackiness agent) and a UV curing type tackiness agent preferably in which a UV curable compound is blended in an acrylic tackiness agent. A preferable embodiment of the active energy beam curing type tackiness agent to be used includes an acrylic tackiness agent containing a side chain acrylate, an acrylate-based crosslinking agent (compound containing poly(meth)acryloyl group; polyfunctional acrylate), and a UV curing type tackiness agent containing an ultraviolet photopolymerization initiator, in particular. The acrylic tackiness agent containing the side chain acrylate means the acrylic polymer in which the acrylate group has been introduced in the side chain. The acrylate-based crosslinking agent is the low-molecular compound illustrated in the above description as the compound containing the poly(meth)acryloyl group. As for the ultraviolet photopolymerization initiator, the compound illustrated in the above description can be used as a representative active energy beam polymerization initiator.

The active energy beam curing type tackiness agent layer 14 has the product of the tensile modulus of elasticity and the thickness of approximately 0.1 to 100 N/m and preferably of approximately 0.1 to 20 N/m at normal temperature (25° C.), before irradiation with the active energy beam; and has the tack force (180° peel peeling test with respect to a silicon mirror wafer at a pulling rate of 300 mm/min) preferably in the range, for instance, of 0.5 N/10 mm to 10 N/10 mm, at normal temperature (25° C.). When the product of the tensile modulus of elasticity and the thickness, and the tack force of the tackiness agent layer before irradiation with the active energy beam deviate from the range, it tends to be difficult to hold and temporarily fix the wafer 2 because the tack force is insufficient.

The feature of the active energy beam curing type tackiness agent layer 14 is to be cured by irradiation with the active energy beam and attain the product of the tensile modulus of elasticity and the thickness at 80° C. of 5×10³ N/m or more and less than 1×10⁵ N/m (preferably 8×10³ N/m or more and less than 1×10⁵ N/m). When the product of the tensile modulus of elasticity and the thickness is less than 5×10³ N/m after irradiation with the active energy beam, a sufficient counteracting force is not produced, the whole surface protection sheet for dicing is deformed to become an indefinite shape such as a bent shape, a waved (wrinkled) shape or the like by a shrinkage stress of the heat-shrinkable film, and the surface protection sheet for dicing cannot cause spontaneous winding.

By being irradiated with the active energy beam, the active energy beam curing type tackiness agent layer 14 can be cured so that the product of the tensile modulus of elasticity and the thickness can be 5×10³ N/m or more and less than 1×10⁵ N/m at 80° C., and accordingly can acquire moderate toughness or stiffness and can show the function as the constraining layer, after having been irradiated with the active energy beam.

When the shrinkable film layer is thermally shrunk, the constraining layer constrains the shrinkage, can produce a counteracting force, for instance, produces a couple by the whole laminated body, and can convert the couple to a driving force for causing winding.

The constraining layer is considered also to have the function of suppressing the secondary shrinkage of the shrinkable film layer 10 in a different direction from the main shrinking direction, and converging the shrinking direction of the shrinkable film layer 10 to one direction, which is considered to have uniaxially-shrinking properties but does not necessarily have uniform uniaxially-shrinking properties. For this reason, it is considered that when the laminated body is heated so as to promote the shrinkage of the shrinkable film layer for instance, the active energy beam curing type tackiness agent layer 14 which shows the function as the constraining layer after having been cured converts a repulsive force with respect to the shrinking force of the shrinkable film layer 10 to a driving force, lifts up the outer edge (one end or opposing two ends) of the laminated body, and spontaneously winds the laminated body toward one direction or the center direction (normally, main shrinking axis direction of shrinkable film layer) from the ends so that the shrinkable film layer 10 side comes inside to form a cylindrical wound body.

Although it is considered that the warp produced by the wafer grinding is produced by an elastic deformation of the shrinkable film layer according to the remaining stress which has remained when the adhesive sheet has been affixed to the wafer, the elastic layer can also further show the function of alleviating the remaining stress and decreasing the warp. In addition, the active energy beam curing type tackiness agent layer 14 which shows the function as the constraining layer after having been cured can prevent a shearing force produced by the shrinkage and deformation of the shrinkable film layer from being transmitted to the wafer 2, and accordingly can prevent damage to the wafer 2 in the peeling operation. Moreover, the active energy beam curing type tackiness agent layer remarkably decreases the tack force with respect to the wafer 2 by being cured, and accordingly can be easily peeled without leaving its glue on the wafer 2 in the peeling operation.

The surface protection sheet for dicing in the present invention can be manufactured preferably by overlapping a shrinkable film layer 10, a constraining layer and an active energy beam curing type tackiness agent layer thereon, and by laminating the layers by appropriately and selectively using lamination means such as a hand roller and a laminater or atmospheric pressure compression means such as an autoclave, according to the purpose.

The active energy beam can include, for instance, infrared rays, visible light, ultraviolet rays, radioactive rays and an electron beam, which can be appropriately selected according to the types of the active energy beam curing type tackiness agent layer of the surface protection sheet for dicing to be used. For instance, when the surface protection sheet for dicing, which has an ultraviolet curing type tackiness agent layer, is used, ultraviolet rays are used as the active energy beam.

The method for generating ultraviolet rays is not limited in particular, can adopt a well-known and conventional generating method, and can include, for instance, a discharge lamp method (arc lamp), a flash method and a laser method. In the present invention, it is preferable to use a discharge lamp method (arc lamp) from the viewpoint of superior industrial productivity, and to use an irradiation method with the use of a high-pressure mercury lamp or a metal halide lamp among the methods from the viewpoint of superior irradiation efficiency.

As for the wavelength of ultraviolet rays, the wavelength in an ultraviolet region can be used without being limited, but it is preferable to use the wavelength of approximately 250 to 400 nm, which is used in a general photopolymerization reaction and used in the above described ultraviolet ray-generating system. The condition of irradiation with ultraviolet rays may be a condition of being capable of initiating the polymerization of the tackiness agent which constitutes the active energy beam curing type tackiness agent layer and curing so that the product of the tensile modulus of elasticity and the thickness at 80° C. can be 5×10³ N/m or more and less than 1×10⁵ N/m; and the irradiation intensity is, for instance, approximately 10 to 1,000 mJ/cm², and preferably is approximately 50 to 600 mJ/cm². When the irradiation strength of ultraviolet rays is less than 10 mJ/cm², the active energy beam curing type tackiness agent layer is insufficiently cured, and it tends to be difficult to show the function as the constraining layer. On the other hand, when the irradiation strength exceeds 1,000 mJ/cm², the active energy beam curing type tackiness agent layer is excessively cured and tends to be cracked.

It is also possible to use a non-active energy beam curing type tackiness agent which employs the above described acrylic tackiness agent as a base agent, for the tackiness agent constituting the tackiness agent layer 14. In this case, the tackiness agent can fit which has a smaller tack force than a peeling stress that works when the cylindrical wound body is produced, and a preferably usable tackiness agent shows, for instance, 6.5 N/10 mm or less (for instance, 0.05 to 6.5 N/10 mm, and preferably 0.2 to 6.5 N/10 mm) in the 180° peel peeing test (at room temperature (25° C.)) with the use of a silicon mirror wafer as a wafer, and shows particularly 6.0 N/10 mm or less (for instance, 0.05 to 6.0 N/10 mm and preferably 0.2 to 6.0 N/10 mm).

A non-active energy beam curing type tackiness agent to be preferably used which employs an acrylic tackiness agent having such a small tack force as a base agent includes an acrylic tackiness agent which has been formed by preparing a copolymer of an alkyl (meth)acrylate [for instance, a C1-C20 alkyl (meth)acrylate such as methyl (meth)acrylate, ethyl (meth)acrylate, butyl (meth)acrylate, 2-ethylhexyl (meth)acrylate and octyl (meth)acrylate], a monomer which has a reactive functional group [for instance, a monomer containing a carboxyl group or an acid anhydride group, such as acrylic acid, methacrylic acid, itaconic acid, fumaric acid and maleic acid anhydride; a monomer containing a hydroxyl group, such as 2-hydroxyethyl (meth)acrylate; a monomer containing an amino group, such as morpholyl (meth)acrylate; and a monomer containing an amide group, such as (meth)acrylamide], and another copolymerizable monomer which is used as needed [for instance, a (meth)acrylate which has an alicyclic hydrocarbon group, such as isobornyl (meth)acrylate, acrylonitrile and the like], and by adding a crosslinking agent which can react with the above described reactive functional group [for instance, an isocyanate crosslinking agent, a melamine crosslinking agent, an epoxy crosslinking agent and the like] to the copolymer to crosslink the monomers.

The tackiness agent layer 14 can be formed by conventional methods such as a method of applying a coating liquid which has been prepared, for instance, by adding a solvent as needed to a tackiness agent and an active energy beam curable compound, onto the surface of the constraining layer 11 (the surface of rigid film layer 13 in the above described example), and a method of applying the above described coating liquid onto a proper release liner (separator) to form a tackiness agent layer, and transcribing (transferring) the tackiness agent layer onto the constraining layer 11. When the transcribing method is used, a void (cavity) occasionally remains in the interface between the tackiness agent layer 14 and the constraining layer 11. In this case, the void can be diffused and vanished by applying warming pressurization treatment such as autoclave treatment. The tackiness agent layer 14 may be any of a monolayer and a multilayer.

Beads such as glass beads and resin beads may also be further added to the component of the tackiness agent layer 14. When glass beads and resin beads are added to the tackiness agent layer 14, the shear modulus of elasticity is enhanced and the tack force tends to be easily lowered. The average particle diameter of the beads is, for instance, 1 to 100 μm, and preferably is approximately 1 to 20 μm. The amount of the beads to be added is, for instance, 25 to 200 parts by weight with respect to 100 parts by weight of the tackiness agent layer 14, and preferably is 50 to 100 parts by weight. When the above described amount of the beads to be added is too large, the beads cause a dispersion failure and it becomes occasionally difficult to apply the tackiness agent. When the above described amount is too small, the above described effect tends to become insufficient.

The thickness of the tackiness agent layer 14 is generally 10 to 200 μm, preferably is 20 to 100 μm, and more preferably is 30 to 60 μm. When the above described thickness is too thin, the tack force becomes insufficient and accordingly it tends to become difficult to hold and temporarily fix the wafer 2. When the above described thickness is too thick, the tackiness agent layer is not preferable because of being uneconomical and being inferior also in handleability.

The surface protection sheet 1 for dicing to be used in the present invention can be manufactured by overlapping a shrinkable film layer 10 and a constraining layer 11 (preferably elastic layer 12 and rigid film layer 13), and by laminating the layers by appropriately and selectively using lamination means such as a hand roller and a laminator or atmospheric pressure compression means such as an autoclave, according to the purpose. In addition, the surface protection sheet for dicing of the present invention may be manufactured by providing a tackiness agent layer 14 on the surface of the constraining layer 11 of the surface protection sheet 1 for dicing, or by overlapping and laminating the constraining layer 11 (or rigid film layer 13) which has been previously provided with the tackiness agent layer 14 on one side with the shrinkable film layer 10 (or shrinkable film layer 10 and elastic layer 12).

When the surface protection sheet 1 for dicing has an active energy beam curable compound in the side of contacting the wafer 2, it is possible to bond the surface protection sheet 1 for dicing on the wafer 2, and irradiating the side of the surface protection sheet 1 for dicing, which contacts the wafer 2, after having been subjected to a dicing process, with an active energy beam to decrease the tack force. Subsequently or coincidentally, the surface protection sheet 1 for dicing is heated with the heat which becomes the cause of the shrinkage of the shrinkable film layer, is spontaneously wound toward one direction (normally toward main shrinking axis direction) from one end of the surface protection sheet 1 for dicing, or toward the center (normally toward main shrinking axis direction) from opposing two ends, forms one or two cylindrical wound bodies, and thereby can be peeled from the wafer 2. The stimulus which becomes the cause of the shrinkage, such as heating, is imparted preferably by irradiation with the active energy beam. Here, when the surface protection sheet 1 for dicing is spontaneously wound toward one direction from one end, one cylindrical wound body is formed (one-direction winding peeling), and when the surface protection sheet 1 for dicing is spontaneously wound toward the center from opposing two ends, two parallel cylindrical wound bodies are formed (two-direction winding peeling).

After the dicing process, for instance, when the tackiness agent layer 14 is an active energy beam curing type tackiness agent layer, the tackiness agent layer 14 is irradiated with an active energy beam, and coincidentally or subsequently, the requisite stimulus which becomes the cause of the shrinkage, such as heating, is imparted to the shrinkable film layer 10 by means of imparting the stimulus which becomes the cause of the shrinkage, such as heating. Then, the tackiness agent layer 14 is cured and loses its tack force, the shrinkable film layer 10 intends to shrink and deform, and the surface protection sheet 1 for dicing is lifted up and winds from the outer edge (or opposing two outer edges). The surface protection sheet 1 for dicing runs by itself to one direction (or two directions of reverse directions (central direction)) while further winding, depending on the conditions of imparting the stimulus which becomes the cause of the shrinkage, such as heating, and forms one piece (or two pieces) of cylindrical wound bodies. In the above description, the cylindrical wound body is not only a cylindrical wound body in which the both ends of the tape contact or overlap each other, but also includes a cylindrical wound body in such a state that the both ends of the tape does not contact each other and a part of the cylinder is opened. At this time, the shrinking direction of the surface protection sheet for dicing is controlled by the constraining layer 11, and accordingly promptly forms the cylindrical wound body while winding to one axial direction. Therefore, the surface protection sheet 1 for dicing can be peeled extremely easily and cleanly from the wafer 2.

When the stimulus which becomes the cause of shrinkage is imparted by heating, the heating temperature can be appropriately selected according to the shrinking properties of the shrinkable film layer 10. The heating temperature is not limited in particular as long as the maximum temperature is, for instance, a temperature at which the wafer is not affected and the surface protection sheet for dicing winds, but, for instance, can be set at 50° C. or more, preferably at 50° C. to 180° C., and further preferably at 70° C. to 180° C. Irradiation with the active energy beam and heating treatment may be simultaneously conducted, or may be conducted step by step. In addition, as for heating, the whole surface of the wafer 2 may be heated not only uniformly but also step by step, and further may be heated partially only for making an initiation site of peeling, which can be appropriately selected according to the purpose of utilizing easy-peelability.

### [Intermediate Layer]

The material which forms an intermediate layer is not limited in particular, and can employ, for instance; the tackiness agents which have been nominated for the tackiness agent layer; various flexible resins such as the polyethylene (PE) which is generally referred to as a resin film, an ethylene-vinylalcohol copolymer (EVA) and an ethylene-ethylacrylate copolymer (EEA); a mixed resin of an acrylic resin and a urethane polymer; and a graft polymer of an acrylic resin and natural rubber.

As for an acrylic monomer for forming the above described acrylic resin, an alkyl(meth)acrylate such as a C1-C20 alkyl (meth)acrylate such as methyl (meth)acrylate, ethyl (meth)acrylate, butyl (meth)acrylate, t-butyl (meth)acrylate, 2-ethylhexyl (meth)acrylate and octyl (meth)acrylate can be used singly, or in mixtures with a monomer [for instance, monomer containing carboxyl group or acid anhydride group, such as acrylic acid, methacrylic acid, itaconic acid, fumaric acid and maleic acid anhydride], which can be copolymerized with the alkyl (meth)acrylate.

As for a material for forming the intermediate layer in the present invention, it is preferable to use a mixed resin of an acrylic resin and a urethane polymer or a graft polymer of an acrylic resin and natural rubber among the materials, from the viewpoint of firm adhesion to the rigid film layer, and is particularly preferable to use the mixed resin of the acrylic resin and the urethane polymer. Here, the urethane polymer can be produced with a well-known and conventional method.

An undercoating layer may be appropriately provided between the intermediate layer and the above described rigid film layer, for the purpose of enhancing the adhesiveness between the intermediate layer and the rigid film layer. In addition, for the purpose of enhancing the adhesiveness between the intermediate layer and the above described tackiness agent layer, the surface of the intermediate layer can be subjected to conventional physical treatment or chemical treatment, such as matte treatment, corona discharge treatment, primer treatment, crosslinking treatment (for instance, chemical crosslinking treatment with the use of silane) and the like.

The intermediate layer can be formed by well-known and conventional methods according to the material forms, and can be formed, for instance, by a method of applying the solution onto the surface of the rigid film layer, when the material is a solution, or by applying the solution onto a suitable release liner (separator) to form an intermediate layer and transcribing (transferring) this layer onto the rigid film layer. In addition, when a flexible resin or a mixed resin is used for the intermediate layer, the methods include a method of extrusion-laminating the resin onto the rigid film layer, and a method of dry-laminating a resin which has been previously formed into a film shape onto the rigid film layer, or affixing the resin onto the rigid film layer through an undercoating agent having tackiness and adhesiveness.

The shear modulus of elasticity of the intermediate layer at 23° C. is approximately 1×10⁴ Pa to 4×10⁷ Pa, from the viewpoints of easy affixing of an adhesive sheet and workability in cutting a tape and the like, and is preferably approximately 1×10⁵ Pa to 2×10⁷ Pa. When the shear modulus of elasticity at 23° C. is less than 1×10⁴ Pa, the intermediate layer protrudes from the outer circumference of the wafer by the grinding pressure for the wafer, and may damage the wafer. When the shear modulus of elasticity at 23° C. exceeds 4×10⁷ Pa, the function of controlling the warp tends to be lowered.

The thickness of the intermediate layer is preferably 10 μm or more, and especially preferably is 30 μm or more (particularly 50 μm or more). When the thickness of the intermediate layer is less than 10 μm, it tends to become difficult to effectively suppress the warping of the wafer due to grinding. In addition, the thickness of the intermediate layer is preferably less than 150 μm so as to keep grinding precision.

In addition, it is preferable that the intermediate layer not only has the function of alleviating the above described tensile stress but also works as a cushion which absorbs the unevenness of the wafer surface during grinding, and the sum of the thicknesses of the intermediate layer and the above described tackiness agent layer is 30 μm or more (especially 50 to 300 μm). On the other hand, when the sum of the thicknesses of the intermediate layer and the above described tackiness agent layer is less than 30 μm, the tack force with respect to the wafer tends to be insufficient, and the intermediate layer cannot sufficiently absorb the unevenness of the wafer surface in an affixing operation. Accordingly, the wafer tends to be damaged and the wafer edge tends to be easily chipped, in the grinding operation. When the sum of the thicknesses of the intermediate layer and the above described tackiness agent layer exceeds 300 μm, the thickness precision is lowered, the wafer tends to be easily damaged in the grinding operation, and the spontaneous winding properties tend to be lowered.

A product of the shear modulus of elasticity and the thickness of the intermediate layer (shear modulus of elasticity×thickness) is, for instance, preferably approximately 15,000 N/m or less at 23° C. (for instance, 0.1 to 15,000 N/m), more preferably approximately 3,000 N/m or less (for instance, 3 to 3,000 N/m), and particularly preferably approximately 1,000 N/m or less (for instance, 20 to 1,000 N/m). When the product of the shear modulus of elasticity and the thickness of the intermediate layer is too large, it becomes difficult to alleviate the tensile stress of a composite substrate formed of a shrinkable film layer/an elastic layer/a rigid film layer, and it tends to become difficult to suppress the warping of the wafer due to grinding. Thus, the intermediate layer cannot sufficiently absorb the unevenness of the wafer surface by rigidity in the affixing operation, accordingly the wafer tends to be damaged, and the wafer edge tends to be easily chipped in the grinding operation. When the product of the shear modulus of elasticity and the thickness of the intermediate layer is too small, the intermediate layer protrudes to the outside of the wafer, which tends to cause the chipping of the edge and cause the damage, and further brings also a lowering action on winding properties.

### [Release Liner]

The surface protection sheet 1 for dicing to be used in the present invention may be provided with a release liner (separator) on a surface of the tackiness agent layer 14, from the viewpoint of the smoothing and protection of the tackiness agent layer 14 of the surface, label processing, the prevention of blocking and the like. The release liner is removed when the surface protection sheet is affixed to the wafer 2, and is not necessarily provided. The release liner to be used is not particularly limited, and a known releasing paper and the like can be used.

A usable release liner includes, for instance, a substrate having a release treatment layer, a low-adhesiveness substrate formed from a fluorine-based polymer, a low-adhesiveness substrate formed from a nonpolar polymer and the like. The above described substrate having the release treatment layer includes, for instance, a plastic film, paper and the like, which have been surface-treated with a release treatment agent of silicone-based, long-chain-alkyl-based and fluorine-based polymers, molybdenum sulfide and the like.

The fluorine-based polymer in the low-adhesiveness substrate formed from the above described fluorine-based polymer includes, for instance, polytetrafluoroethylene, polychlorotrifluoroethylene, polyvinyl fluoride, polyvinylidene fluoride, a tetrafluoroethylene-hexafluoropropylene copolymer, and a chlorofluoroethylene-vinylidenefluoride copolymer.

The nonpolar polymer in the low-adhesiveness substrate formed from the above described nonpolar polymer includes, for instance, an olefin-based resin (for instance, polyethylene, polypropylene and the like). The release liner can be formed with a known or conventional method.

The thickness of the above described release liner is not limited in particular, but is, for instance, 10 to 200 μm, and preferably is approximately 25 to 100 μm. In addition, the release liner may be subjected to ultraviolet ray protection treatment and the like as needed, so as to prevent the active energy beam curing type tackiness agent layer from being cured by environmental ultraviolet rays.

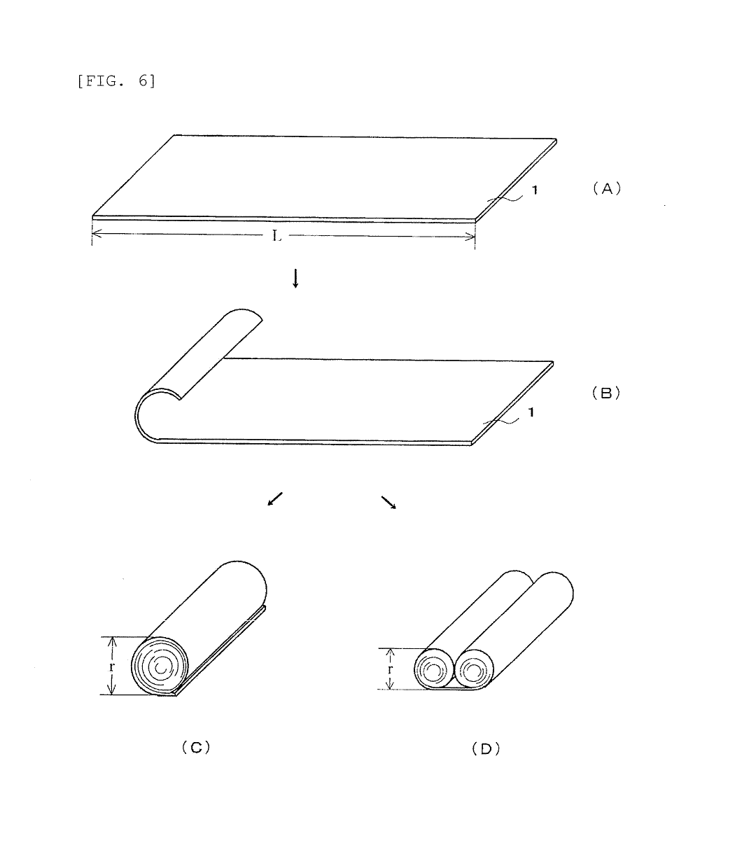

FIG. 6 shows the state in which the surface protection sheet for dicing to be used in the present invention independently and spontaneously winds. In FIG. 6, FIG. 6(A) is a view illustrating the surface protection sheet 1 for dicing before a stimulus which becomes the cause of the shrinkage, such as heat, is applied to the shrinkable film layer; FIG. 6(B) is a view illustrating the state at the time when the surface protection sheet for dicing, in which the stimulus that becomes the cause of the shrinkage, such as heat, has been applied to the shrinkable film layer (when having the active energy beam curing type tackiness agent layer, the adhesive sheet after the active energy beam curing type tackiness agent layer has been cured and the tack force has been lowered), has started winding to one direction (normally to the main shrinking axis direction of the shrinkable film layer) from the outer edge (one end) of the sheet; FIG. 6(C) is a view illustrating the state (one-direction winding) at the time when the sheet has finished winding and one piece of a cylindrical wound body has been formed; and FIG. 6(D) is a view illustrating the state (two-direction winding) at the time when the sheet has spontaneously wound toward the center from opposing two ends (normally to the main shrinking axis direction of the shrinkable film layer) and two cylindrical wound bodies have been formed.

Here, whether the adhesive sheet winds in one direction or winds in two directions varies depending on the tack force of the active energy beam curing type tackiness agent layer with respect to the shrinkable film layer after having been irradiated with the active energy beam, the product of the tensile modulus of elasticity and the thickness, and the like, when the adhesive sheet has the active energy beam curing type tackiness agent layer.

In FIG. 6, L shows the length (the diameter when the sheet is circular) in the winding direction (normally in main shrinking axis direction of shrinkable film layer) of the surface protection sheet for dicing (FIG. 6(A)), and r shows a diameter (the maximum diameter when the diameter of the cylindrical wound body in the longitudinal direction of the wound body is not constant as in the case of a circular sheet and the like) of the formed cylindrical wound body (FIG. 6(C) and FIG. 6(D)). In the surface protection sheet for dicing in the present invention, the value of r/L is a value defined by the Example which will be described later, and is preferably in the range of 0.001 to 1. Here, L can be set, for instance, at 3 to 2,000 mm, and preferably at 3 to 1,000 mm. Here, even if the laminated sheet does not have the tackiness agent layer, the laminated sheet shows the same behavior as that of the adhesive sheet having the tackiness agent layer, concerning the spontaneous winding properties.

The length in the direction perpendicular to L in the adhesive sheet can be set, for instance, at 3 to 2,000 mm, and preferably at approximately 3 to 1,000 mm. The value of r/L can be controlled into the above described range by adjusting the type, composition, thickness and the like of the material in each layer of the shrinkable film layer 10, the constraining layer 11 (the elastic layer 12 and the rigid film layer 13) and the tackiness agent layer 14, and particularly by adjusting the shear modulus of elasticity and the thickness of the elastic layer 12 which constitutes the constraining layer 11, and Young's modulus and the thickness of the rigid film layer 13. The value of r/L can be controlled into the above described range by adjusting the type, composition, thickness and the like of the material of each layer of the shrinkable film layer and the active energy beam curing type tackiness agent layer, when the laminated sheet has the active energy beam curing type tackiness agent layer, and particularly by adjusting the tensile modulus of elasticity and the thickness of the active energy beam curing type tackiness agent layer (tackiness agent layer having function working as constraining layer) after having been irradiated with the active energy beam. In this example, the shape of the surface protection sheet for dicing is a rectangle but is not limited to this. The shape can be appropriately selected according to the purpose, and may be any of a circular shape, an elliptical shape, a polygonal shape and the like.

Here, the surface protection sheet for dicing to be used in the present invention winds similarly even if the length L of the winding direction of the sheet becomes longer. Accordingly, the lower limit of the ratio (r/L) of the diameter r of the cylindrical wound body which is formed by the spontaneous winding of the surface protection sheet for dicing when the stimulus which becomes the cause of the shrinkage, such as heating, has been imparted to the surface protection sheet for dicing to make the surface protection sheet for dicing shrink, to the length L in the winding direction of the surface protection sheet for dicing decreases as the length L of the winding direction of the sheet increases.

### EXAMPLES

The surface protection sheet for dicing to be used in the method according to the present invention will be described in detail below on the basis of the Examples, but the present invention is not limited to the methods which use the surface protection sheet for dicing of these Examples. Here, the shear modulus of elasticity of the elastic layer and the rigid film layer, and the tack force of the elastic layer with respect to the shrinkable film were measured in the following way. In addition, the r/L which is an indicator of determining whether the sheet functions as a cylindrical wound body was defined by the method which will be shown below.

### [Measurement of Young's Modulus (80° C.) of Rigid Film Layer]

The Young's modulus of the rigid film layer was measured with the following method according to JIS K7127. Autograph AG-1kNG (with warming hood) made by SHIMADZU CORPORATION was used as a tensile tester. The rigid film cut out to a length of 200 mm×width of 10 mm was attached to the tensile tester with a distance between chucks of 100 mm. After the temperature of atmosphere was adjusted to 80° C. by the warming hood, the sample was pulled at a pulling rate of 5 mm/min, and a measurement value of the stress-strain correlation was obtained. The loads were measured at two points of strains of 0.2% and 0.45%, and the Young's moduli were obtained. This measurement was repeated 5 times for the same sample, and the average value was adopted.

### [Measurement of Shear Modulus of Elasticity (80° C.) of Elastic Layer]

The shear modulus of elasticity of the elastic layer was measured with the following method. The elastic layers described in each of Examples and Comparative Examples were produced so as to have thicknesses of 1.5 to 2 mm and then were stamped by a punch with a diameter of 7.9 mm, and samples for measurement were obtained. The measurement was conducted by using a viscoelasticity spectrometer (ARES) made by Rheometric Scientific, Inc. and by setting a chuck pressure at 100 g-force and a shear at a frequency of 1 Hz [while using a parallel plate of 8 mm made from stainless steel (made by T A instruments Inc., model 708. 0157)]. Then, the shear modulus of elasticity at 80° C. was measured.

[Measurement of Tack Force of Elastic Layer with Respect to Shrinkable Film]

The tack force of the elastic layer with respect to the shrinkable film was measured with the 180° peel peeling test (50° C.). The laminated sheet [which was produced similarly to the surface protection sheet for dicing except that a tackiness agent layer (the active energy beam curing type tackiness agent layer or the non-active energy beam curing type tackiness agent layer) was not provided, but was already irradiated with ultraviolet rays with an intensity of 500 mJ/cm², for a laminated sheet which contained an ultraviolet ray reactive crosslinking agent in the elastic layer but was not yet irradiated with ultraviolet rays] was cut to a size with a width of 10 mm, the face of the rigid film layer side was affixed to a rigid support substrate (silicon wafer) by using an adhesive tape, a pulling jig of the peel peeling tester was affixed to the surface of the shrinkable film layer side with the use of an adhesive tape, and the jig was mounted on a heating stage (heater) of 50° C. so that the rigid support substrate contacts the heating stage. The pulling jig was pulled toward the direction of 180° at a pulling rate of 300 mm/min, and the force (N/10 mm) of the time when peeling occurred between the shrinkable film layer and the elastic layer was measured. The thickness of the rigid support substrate was standardized to 38 μm so as to eliminate a measurement error caused by difference between the thicknesses of the rigid support substrates.

[Measurement of Tack Force of Non-Active Energy Beam Curing Type Tackiness Agent Layer with Respect to Silicon Mirror Wafer]

Laminated bodies of two types of the non-active energy beam curing type tackiness agents obtained in the following Manufacture Examples 2 and 4 were affixed to polyethylene terephthalate substrates (with thickness of 38 μm) with a hand roller. The product was cut to a width of 10 mm, a release sheet was removed, and the resultant product was affixed to the 4-inch mirror silicon wafer (made by Shin-Etsu Handotai Co., Ltd., trade name “CZ-N”) with a hand roller. This was affixed to the pulling jig of the peel peeling tester with an adhesive tape. The pulling jig was pulled toward the direction of 180° at a pulling rate of 300 mm/min, and the force (N/10 mm) of the time when peeling occurred between the shrinkable film layer and the elastic layer was measured.

The tack force with respect to the 4-inch mirror silicon wafer (made by Shin-Etsu Handotai Co., Ltd., trade name “CZ-N”) was measured also on the active energy beam curing type tackiness agent layers obtained in the following Manufacture Examples 1 and 3, in a similar method to the above description except that the tackiness agent layers were exposed to ultraviolet rays of 500 mJ/cm² before measurement. As a result, the tack forces were 0.3 N/10 mm or less in any of the tackiness agents, and were sufficiently lowered to a peelable value. For this reason, in the following Examples, the description of the tack force with respect to the silicon wafer of the active energy beam curing type tackiness agent layer shall be omitted.

### [Measurement of r/L Value]

The sheet prepared by cutting the surface protection sheet for dicing obtained in the following description to 100×100 mm and then using the active energy beam curing type tackiness agent was irradiated with ultraviolet rays of approximately 500 mJ/cm². One end of the surface protection sheet for dicing was immersed in warm water of 80° C. along the shrinking axis direction of the shrinkable film to promote deformation. As for the sheet which has been deformed to become the cylindrical wound body, the diameter was measured by using a ruler, and the value was divided by 100 mm to be determined as r/L. The laminated sheet which does not contain the tackiness agent layer shows the same behavior as an adhesive sheet which has a tackiness agent layer, concerning the spontaneous winding properties.

### Manufacture of Tackiness Agent Layer

### Manufacture Example 1

### Manufacture of Active Energy Beam Curing Type Tackiness Agent Layer (1)

An acrylic polymer having a methacrylate group in the side chain was produced by combining 50% of hydroxyl groups originating in 2-hydroxyethyl acrylate of an acrylic polymer [which was produced by copolymerizing a composition: 2-ethylhexyl acrylate:morpholyl acrylate:2-hydroxyethyl acrylate=75:25:22 (molar ratio)] with methacryloyloxyethyl isocyanate (2-isocyanato ethyl methacrylate).

An active energy beam curing type tackiness agent was prepared by mixing 15 parts by weight of ARONIX M320 (made by Toagosei Co., Ltd.; trimethylol-propane-PO-denaturated (n≠2) triacrylate), which is a photopolymerizable crosslinking agent, one part by weight of a photoinitiator (made by Ciba-Geigy Corporation, trade name “IRGACURE 651”), and one part by weight of an isocyanate crosslinking agent (trade name “CORONATE L”), with respect to 100 parts by weight of the acrylic polymer having the methacrylate group in the side chain.

A laminated body in which the active energy beam curing type tackiness agent layer with a thickness of 35 μm was provided on the release sheet was obtained by coating the obtained active energy beam curing type tackiness agent on the release sheet (made by Mitsubishi Polyester Film Corporation, trade name “MRF38”) with the use of an applicator, and then by drying a volatile matter such as a solvent.

### Manufacture Example 2

### Manufacture of Non-Active Energy Beam Curing Type Tackiness Agent Layer (1)

A non-active energy beam curing type tackiness agent was prepared by mixing 0.7 parts by weight of an epoxy-based crosslinking agent (made by MITSUBISHI GAS CHEMICAL COMPANY, INC., trade name “TETRAD C”) and 2 parts by weight of an isocyanate-based crosslinking agent (trade name “CORONATE L”) with 100 parts by weight of an acrylic copolymer [which has been produced by copolymerizing a mixture of butyl acrylate:acrylic acid=100:3 (weight ratio)].

A laminated body in which the non-active energy beam curing type tackiness agent layer with a thickness of 30 μm was provided on the release sheet was obtained by coating the obtained non-active energy beam curing type tackiness agent on the release sheet (made by Mitsubishi Polyester Film Corporation, trade name “MRF38”) with the use of an applicator, and then by drying a volatile matter such as a solvent.

### Manufacture Example 3

### Manufacture of Active Energy Beam Curing Type Tackiness Agent Layer (2)

An acrylic polymer having a methacrylate group in the side chain was produced by combining 80% of hydroxyl groups originating in 2-hydroxyethyl acrylate of an acrylic polymer [which was produced by copolymerizing a composition: butyl acrylate:ethyl acrylate:2-hydroxyethyl acrylate=50:50:20 (molar ratio)] with methacryloyloxyethyl isocyanate (2-isocyanato ethyl methacrylate).

An active energy beam curing type tackiness agent was prepared by mixing 100 parts by weight of a compound with a trade name of “Shikoh UV1700” made by The Nippon Synthetic Chemical Industry Co., Ltd., as a compound containing two or more functional groups having a carbon-carbon double bond, 3 parts by weight of a photoinitiator (made by Ciba-Geigy Corporation, trade name “IRGACURE 184”) and 1.5 parts by weight of an isocyanate crosslinking agent (trade name “CORONATE L”) with respect to 100 parts by weight of the acrylic polymer having the methacrylate group in the side chain.

A laminated body in which the active energy beam curing type tackiness agent layer with a thickness of 30 μm was provided on the release sheet was obtained by coating the obtained active energy beam curing type tackiness agent on the release sheet (made by Mitsubishi Polyester Film Corporation, trade name “MRF 38”) with the use of an applicator, and then by drying a volatile matter such as a solvent.

### Manufacture Example 4

### Manufacture of Non-Active Energy Beam Curing Type Tackiness Agent Layer (2)

A non-active energy beam curing type tackiness agent was prepared by mixing 0.7 parts by weight of an epoxy-based crosslinking agent (made by MITSUBISHI GAS CHEMICAL COMPANY, INC., trade name “TETRAD C”) and 2 parts by weight of an isocyanate-based crosslinking agent (trade name “CORONATE L”) with 100 parts by weight of an acrylic copolymer [which has been produced by copolymerizing a mixture of butyl acrylate:acrylic acid=100:3 (weight ratio)].

A laminated body in which the non-active energy beam curing type tackiness agent layer with a thickness of 30 μm was provided on the release sheet was obtained by coating the obtained non-active energy beam curing type tackiness agent on the release sheet (made by Mitsubishi Polyester Film Corporation, trade name “MRF 38”) with the use of an applicator, and then by drying a volatile matter such as a solvent.

### Reference Example 1

### Manufacture of Surface Protection Sheet for Dicing Formed of Shrinkable Film Layer/Constraining Layer (Elastic Layer/Rigid Film Layer)/Active Energy Beam Curing Type Tackiness Agent

A constraining layer was formed by preparing a solution by mixing 100 parts by weight of an ester-based polymer [which was produced by copolymerizing PLACCEL CD220PL made by Daicel Chemical Industries, Ltd.: sebacic acid=100:10 (weight ratio)] and 4 parts by weight of “CORONATE L” (crosslinking agent, made by Nippon Polyurethane Industry Co., Ltd.) and dissolving the mixture in ethyl acetate, and applying and drying the solution onto the face free from print-facilitating treatment of a polyethylene terephthalate film (PET film with thickness of 38 μm, made by Toray Industries, Inc., trade name “Lumirror S105”, product with print-facilitating treatment on one face) as the rigid film layer. A laminated sheet (having ester-based tackiness agent layer with thickness of 30 μm) was obtained by overlapping a shrinkable film layer (uniaxially stretched polyester film with thickness of 30 μm made by Toyobo Co., Ltd., trade name “Space clean S7053”) on the constraining layer, and laminating the layers with a hand roller.

The active energy beam curing type tackiness agent layer (1) side of the laminated body obtained in the Manufacture Example 1 was laminated with a rigid film layer side of the laminated sheet obtained in the above description. The layers of the resulting laminated body were firmly adhered to each other by passing the laminated body through a laminator, and the surface protection sheet for dicing was obtained which was formed of shrinkable film layer/constraining layer [elastic layer (ester-based tackiness agent layer)/rigid film layer (PET film layer)]/active energy beam curing type tackiness agent (1) layer/release sheet.

### Reference Example 2

### Manufacture of Surface Protection Sheet for Dicing Formed of Shrinkable Film Layer/Constraining Layer (Elastic Layer/Rigid Film Layer)/Non-Active Energy Beam Curing Type Tackiness Agent

A constraining layer was formed by preparing a solution by mixing 100 parts by weight of an ester-based polymer [which was produced by copolymerizing PLACCEL CD220PL made by Daicel Chemical Industries, Ltd.: sebacic acid=100:10 (weight ratio)] and 4 parts by weight of “CORONATE L” (crosslinking agent, made by Nippon Polyurethane Industry Co., Ltd.) and dissolving the mixture in ethyl acetate, and applying and drying the solution onto the face free from corona treatment of a polyethylene terephthalate film (PET film with thickness of 38 μm, made by Toray Industries, Inc., trade name “Lumirror S105”, product having one face corona-treated) as the rigid film layer. A laminated sheet (having ester-based tackiness agent layer with thickness of 30 μm) was obtained by overlapping a shrinkable film layer (uniaxially stretched polyester film with thickness of 30 μm made by Toyobo Co., Ltd., trade name “Space clean S7053”) on the constraining layer, and laminating the layers with a hand roller.

The non-active energy beam curing type tackiness agent layer (1) side of the laminated body obtained in the Manufacture Example 2 was laminated with a rigid film layer side of the laminated sheet obtained in the above description. The layers of the resulting laminated body were firmly adhered to each other by passing the laminated body through a laminator, and the protection tape was obtained which was formed of shrinkable film layer/constraining layer [elastic layer (ester-based tackiness agent layer)/rigid film layer (PET film layer)]/non-active energy beam curing type tackiness agent (1) layer/release sheet.

In the above described Reference Examples 1 and 2, the thermal shrinkage rate in the main shrinking direction of the above described shrinkable film layer is 70% or more at 100° C., the shear modulus of elasticity (80° C.) of the ester-based tackiness agent layer (elastic layer) is 2.88×10⁵ N/m², and the product of the shear modulus of elasticity and the thickness is 8.64 N/m. The tack force (50° C.) of the ester-based tackiness agent layer (elastic layer) with respect to the shrinkable film layer was 13 N/10 mm.

In addition, the Young's modulus of a PET film layer (rigid film layer) at 80° C. is 3.72×10⁹ N/m², and the product of the Young's modulus and the thickness is 1.41×10⁵ N/m. The r/L was 0.06.

### Reference Example 3

### Manufacture of Surface Protection Sheet for Dicing Formed of Shrinkable Film Layer/Constraining Layer (Elastic Layer/Rigid Film Layer)/Active Energy Beam Curing Type Tackiness Agent>

A constraining layer was formed by preparing a polymer solution by dissolving 100 parts by weight of an acrylic polymer (made by DAIICHI LACE KK, trade name “Reocoat R1020S”), 10 parts by weight of a pentaerythritol-denaturated acrylate crosslinking agent (made by Nippon Kayaku Co., Ltd., trade name “DPHA40H”), 0.25 parts by weight of “TETRAD C” (crosslinking agent, made by MITSUBISHI GAS CHEMICAL COMPANY, INC.), 2 parts by weight of “CORONATE L” (crosslinking agent, made by Nippon Polyurethane Industry Co., Ltd.), and 3 parts by weight of “IRGACURE 651” (photoinitiator, made by Ciba-Geigy Corporation) in methyl ethyl ketone, and applying and drying the solution onto one face of a polyethylene terephthalate film (PET film with thickness of 38 μm, made by Toray Industries, Inc., trade name “Lumirror S10”) as the rigid film layer. A laminated sheet (having acrylic tackiness agent layer with thickness of 30 μm) was obtained by further overlapping a shrinkable film layer (uniaxially stretched polyester film with thickness of 60 μm made by Toyobo Co., Ltd., trade name “Space clean S5630”) on the constraining layer, and laminating the layers with a hand roller.

The active energy beam curing type tackiness agent layer (2) side of the laminated body formed of the active energy beam curing type tackiness agent layer (2)/release sheet obtained in the Manufacture Example 3 was laminated with the rigid film layer side of the laminated sheet obtained in the above description.

The layers of the resulting laminated body were firmly adhered to each other by passing the laminated body through a laminator, and the surface protection sheet for dicing was obtained, which was formed of shrinkable film layer/constraining layer [acrylic tackiness agent layer (elastic layer)/PET film layer (rigid film layer)]/active energy beam curing type tackiness agent (2) layer/release sheet.

### Reference Example 4

### Manufacture of Surface Protection Sheet for Dicing Formed of Shrinkable Film Layer/Constraining Layer (Elastic Layer/Rigid Film Layer)/Non-Active Energy Beam Curing Type Tackiness Agent (2)

The surface protection sheet for dicing was obtained similarly to Example 1 except that the active energy beam curing type tackiness agent layer (2) in Reference Example 3 was replaced with the non-active energy beam curing type tackiness agent layer (2) obtained in Manufacture Example 4.

In the above described Reference Examples 3 and 4, the thermal shrinkage rate of the main shrinking direction of the above described heat-shrinkable film layer was 70% or more at 100° C. In addition, the shear modulus of elasticity (80° C.) of the acrylic tackiness agent layer (elastic layer) was 0.72×10⁶ N/m², the product of the shear modulus of elasticity and the thickness was 21.6 N/m, and the tack force (50° C.) of the acrylic tackiness agent layer (elastic layer) with respect to the shrinkable film layer was 4.4 N/10 mm. Furthermore, the Young's modulus at 80° C. of the PET film layer (rigid film layer) was 3.72×10⁹ N/m², and the product of the Young's modulus and the thickness was 1.41×10⁵ N/m. The r/L was 0.045.

### Example 1

A spontaneously winding sheet which is the surface protection sheet for dicing was stuck onto the circuit face of an 8-inch silicon wafer. Then, the back surface side was back-ground by a device with a trade name of “DFG-8560” made by DISCO Corporation, and was processed to a thickness of 50 μm. Next, a dicing tape (EM-500M2AJ made by NITTO DENKO CORPORATION) was stuck onto the polished-surface side of the silicon wafer, the resultant silicon wafer was fixed to a ring frame (made by DISCO Corporation), and the silicon wafer was fully cut and diced into a size of 10 mm×10 mm together with the surface protection sheet for dicing by using a dicing device (DFD-651).

Subsequently, the silicon wafer which was fixed to the ring frame was charged into an oven, and was heated there for 30 minutes at 60° C. After the silicon wafer was cooled to ordinary temperature, the silicon wafer and the surface protection sheet for dicing were simultaneously peeled from the dicing tape by using a die bonder (FED-1780FAM made by DISCO Corporation). The silicon wafer is adequate which has a little push-up amount of a pin when being peeled, and the push-up amount was evaluated as peelability. In addition, the crack (quality) in the chip of the semiconductor wafer was checked. The results of the peelability and the quality of the chip are shown in Table 1.

### Comparative Example 1

The back grinding tape ((ELPUB-2153D) made by NITTO DENKO CORPORATION) was stuck onto the circuit face of the 8-inch silicon wafer, and the back surface side of the silicon wafer was processed to a thickness of 50 μm by using the polishing device (DFG8560 made by DISCO Corporation). Next, a dicing tape (EM-500M2AJ made by NITTO DENKO CORPORATION) was stuck onto the polished surface side of the silicon wafer, and the resultant silicon wafer was fixed to a ring frame (made by DISCO Corporation). The back grinding tape was peeled, and the silicon wafer was fully cut and diced into a size of 10 mm×10 mm by using a dicing device (made by DISCO Corporation).

### Comparative Example 2

In the method of Comparative Example 1, the silicon wafer was fully cut and diced into a size of 10 mm×10 mm by using a dicing device (made by DISCO Corporation) without peeling the back grinding tape.

TABLE 1

| | | Push-up amount (μm) | | | | |
|---|---|---|---|---|---|---|
| | | 420 | 440 | 460 | 480 | 500 |
| Example 1 | Peelability | 100% | 100% | 100% | 100% | 100% |
| | Quality | 100% | 100% | 100% | 100% | 100% |
| Comparative | Peelability | 0% | 0% | 40% | 100% | 100% |
| Example 1 | Quality | — | — | 40% | 100% | 100% |
| Comparative | Peelability | 0% | 0% | 0% | 60% | 40% |
| Example 2 | Quality | — | — | 0% | 60% | 40% |

In Example 1, the wafer was subjected to dicing and picking up operations with the use of the surface protection sheet for dicing of the present invention, and thereby showed a peelability of 100% even though the push-up amount of a needle was as small as 420 μm, in other words, 100% of the chips could be peeled off. Furthermore, at the time, the quality was 100%, the chips free from defects such as a crack were 100%, and thus the quality of the obtained chip was also adequate.

In Comparative Examples 1 and 2, the push-up amount of the needle necessary for picking up 100% of the chips was 480 μm or more, which was more than the push-up amount in Example 1. Because of this, the force applied to the chip increased, and the cracks tended to easily occur in the chip.

1. A processing method comprising sticking a surface protection sheet for dicing onto a semiconductor wafer; and sticking a dicing tape onto a back surface side of the wafer and then cutting the wafer together with the surface protection sheet for dicing into small pieces to form chips, wherein one part of the chip is peeled off from the dicing tape by a shrinking stress which has been generated by a stimulus given to the surface protection sheet for dicing, and then the chip is peeled off from the dicing tape.

2. The processing method according to claim 1, further comprising using the surface protection sheet for dicing, which comprises a heat-shrinkable film for at least one layer, which shows a thermal shrinkage rate of 3 to 90% in the temperature range of 40 to 180° C.

3. The processing method according to claim 1, wherein the surface protection sheet for dicing to be used has a tack force of 0.01 N/20 mm or more when heated at 40 to 75° C. (90° peel peeling test with respect to the silicon wafer at a pulling rate of 300 mm/min).

4. The processing method according to claim 1, further comprising polishing or etching the back surface side of the wafer so as to have a predetermined thickness before the dicing tape is stuck thereto.
